(19) United States
(12) Patent Application Publication
(10) Pub. No.: US 2008/0203464 A1
(43) Pub. Date: Aug. 28, 2008

(54) ELECTRICALLY ALTERABLE NON-VOLATILE MEMORY AND ARRAY

(76) Inventor: Chih-Hsin Wang, San Jose, CA (US)

Correspondence Address: HARNESS, DICKEY & PIERCE P.L.C., 5445 CORPORATE DRIVE, SUITE 200, TROY, MI, 48098, US

(21) Appl. No.: 11/932,481

(22) Filed: Oct. 31, 2007

Related U.S. Application Data
(63) Continuation-in-part of application No. 11/169,399, filed on Jun. 28, 2005.
Application No. 11/169,399 is a continuation-in-part of application No. 11/007,907, filed on Dec. 8, 2004, now Pat. No. 7,115,942.
Application No. 11/007,907 is a continuation-in-part of application No. 11/120,691, filed on May 2, 2005.
(60) Provisional application No. 60/917,188, filed on May 10, 2007.
(60) Provisional application No. 60/585,238, filed on Jul. 1, 2004.
(60) Provisional application No. 60/626,326, filed on Nov. 8, 2004.

(51) Int. Cl. H01L 29/76; H01L 21/336

(52) U.S. Cl. 257/321; 438/261; 257/E21.422; 257/E29.129

(57) ABSTRACT

A memory device, array and method of arranging where the memory device includes a memory cell region including a plurality of memory cells. Each memory cell includes a source, a drain and a channel between the source and the drain, a channel dielectric, a charge storage region and an electrically alterable conductor-material system in proximity to the charge storage region. Cell lines extend among the memory cells. A connection region is provided for electrically coupling contacts and one or more of the cell lines. A non-memory region has embedded logic. Memory cells are arrayed at a cell pitch, with cell lines extending from cell to cell and arrayed substantially at the cell pitch, and with contacts arrayed substantially at the cell pitch forming a high density memory device.

### CROSS-REFERENCED APPLICATIONS

This application is a continuation-in-part of patent application Ser. No. 11/169,399, filed Jun. 28, 2005; US 2006/0001053 entitled METHOD AND APPARATUS TRANSPORTING CHARGES IN SEMICONDUCTOR DEVICE AND SEMICONDUCTOR MEMORY DEVICE, Pub. Date: Jan. 5, 2006; Inventor: Chih-Hsin Wang. The Ser. No. 11/169,399 application is a continuation-in-part of application Ser. No. 11/007,907 filed Dec. 8, 2004. The Ser. No. 11/169,399 application is a continuation-in-part of application Ser. No. 11/120,691 filed May 2, 2005. The Ser. No. 11/169,399 application claims the benefit under 35 USC 119(e) of application Ser. No. 60/585,238 filed Jul. 1, 2004. The Ser. No. 11/169,399 application claims the benefit under 35 USC 119(e) of application Ser. No. 60/626,326 filed Nov. 8, 2004. application Ser. Nos. 11/169,399; 11/007,907; 11/120,691; 60/585,238; and 60/626,326 are hereby incorporated by reference in each of their entireties in the present application.

This application claims the benefit under 35 USC 119(e) of Provisional Patent Application U.S. Ser. No. 60/917,188 entitled METHOD FORMING ELECTRICAL ALTERABLE NON-VOLATILE MEMORY AND ARRAY, filed May 10, 2007; Inventor: Chih-Hsin Wang. Application Ser. No. 60/917,188 is hereby incorporated by reference in its entirety in the present application.

### TECHNICAL FIELD

The present specification relates to semiconductor devices and semiconductor memory devices and to methods for arranging electrically alterable non-volatile memories and arrays.

### BACKGROUND

Non-volatile semiconductor memory cells permitting charge storage capability are well known in the art. The charges are typically stored in a floating gate to define the states of a memory cell. The states can be two levels or more than two levels (for multi-level state storage). Mechanisms such as channel hot electron injection (CHEI), source-side injection (SSI), Fowler-Nordheim tunneling (FN), and Band-to-Band Tunneling (BTBT) induced hot-electron-injection can be used to alter the states of such cells in program and/or erase operations. Examples employing such mechanisms for memory operations are described in U.S. Pat. Nos. 4,698,787, 5,029,130, 5,792,670 and 5,966,329 for CHEI, SSI, FN, and BTBT mechanisms, respectively.

All the above mechanisms, however, have poor injection efficiency (defined as the ratio of number of carriers collected to the number of carriers supplied). Further, these mechanisms require high voltages to support the memory operation, and a voltage as high as 10V is often seen. It is believed that the high voltage demands stringent control on the quality of the insulator surrounding the floating gate. The memories operated under these mechanisms thus are vulnerable to manufacturing and reliability problems.

In light of the foregoing problems, it is an object of the present invention to provide an insulating barrier in a conductor-insulator system that can be operated to enhance carrier injection efficiency and to reduce operation voltages. It is another object of the present invention to provide charge carriers (electrons or holes) transporting with tight energy distribution and high injection efficiency.

There is a need to further improve memory cells, arrays and logic and to further improve methods of arranging them, for increased cell pitches, cell densities and performance enhancement.

Other objects of the inventions and further understanding on the objects will be realized by referencing to the specifications and drawings.

### SUMMARY

Embodiments of the present invention include a memory device, a memory array and a method of arranging memory devices and arrays. The memory device includes a memory cell region including a plurality of memory cells. Each memory cell includes a source, a drain and a channel between the source and the drain, a channel dielectric, a charge storage region and an electrically alterable conductor-material system in proximity to the charge storage region. The memory device includes a plurality of cell lines extending among the memory cells and includes a plurality of contacts. The memory device includes a connection region for electrically coupling one or more of the contacts and one or more of the cell lines. The memory device includes a non-memory region having embedded logic.

In one embodiment, the conductor-material system includes a first conductive region, a dielectric region and a second conductive region disposed adjacent to and insulated from the first conductive region by the dielectric region. The charge storage region is a third region disposed adjacent to and insulated from the second conductive region.

In another embodiment, the contacts of the memory device are selected from the group consisting of self-aligned contacts, borderless contacts and combinations thereof where the contacts are located in self-aligned holes and borderless holes. The contacts and contact holes are “self-aligned” in that they extend through semiconductor layers of the memory device with an arrangement of the materials and layers such that the holes and contacts are preferentially constrained to alignment at desired locations, for example, by contact insulators. The contacts and contact holes are “borderless” in that they extend through semiconductor layers of the memory device where the arrangement of the materials and layers do not preferentially constrain the locations of contact holes and the contacts.

In a further embodiment, the memory device has one or more of the contacts in contact holes arranged substantially in alignment with the cell lines, where the conductor-material system has one or more conductors, and where the contact holes include sidewall insulators to prevent the contacts from shorting to the conductors.

In a still further embodiment, the connection region of the memory device includes a plurality of contact insulators where each of one or more of the contacts is located in proximity to a pair of the contact insulators.

In a still additional embodiment, the memory device includes the memory cell region having the plurality of memory cells arrayed at a cell pitch, with the plurality of cell lines extending from cell to cell and arrayed substantially at the cell pitch, and with the plurality of contacts arrayed substantially at the cell pitch with one or more of the contacts electrically coupling to one or more cell lines.

In a still another embodiment, the memory device has one or more isolations. In a still additional embodiment, the memory device has the plurality of cell lines including bit lines at a bit-line pitch and wherein the isolation is included in the memory cell region occurring at an isolation pitch greater than the bit-line pitch.

The method of arranging a memory device includes, in a memory region, arranging a memory cell region including, arranging a plurality of memory cells where for each memory cell, a source, a drain and a channel between the source and the drain are arranged, a channel dielectric is arranged, a charge storage region is arranged, and an electrically alterable conductor-material system in proximity to the charge storage region is arranged. The method further includes arranging a plurality of contacts, arranging a connection region for electrically coupling one or more of the contacts and one or more of the cell lines and arranging a non-memory region having embedded logic.

In a further embodiment of the method, the plurality of contacts are arranged by selecting from the group consisting of arranging self-aligned contacts, arranging borderless contacts and combinations thereof.

The foregoing and other objects, features and advantages of the invention will be apparent from the following detailed description in conjunction with the drawings.

### BRIEF DESCRIPTION OF THE DRAWINGS

FIG. 1A depicts a cross-sectional view of a cell structure to be arranged in accordance with one embodiment of the present specification.

FIG. 1B depicts a schematic representation of the cell of FIG. 1A.

FIG. 2A depicts a cross-sectional view of another cell structure to be arranged in accordance with another embodiment of the present specification.

FIG. 2B depicts a cross-sectional view of an additional cell structure to be arranged in accordance with another embodiment of the present specification.

FIG. 2C depicts a cross-sectional view of a still additional cell structure to be arranged in accordance with another embodiment of the present specification.

FIG. 3 depicts a schematic diagram showing the array architecture for memory cells of the FIG. 2A type arranged in a memory cell region.

FIG. 4A depicts a schematic diagram of a of a memory device having a memory region formed of cells of the FIG. 1A type and of embedded logic in non-memory regions.

FIG. 4B depicts a schematic diagram of a memory device having a memory region formed of cells of the FIG. 1A type and of non-memory regions including a non-memory region having aligned embedded logic.

FIG. 5 depicts a schematic diagram of a of a memory device having a memory region formed of cells of the FIG. 2A type and of non-memory regions including a non-memory region having aligned embedded logic.

FIG. 6 depicts a generalized step sequence diagram for arranging a cell structure in a memory array in accordance with the present specification.

FIG. 7 depicts a top plan view of a semiconductor substrate used as the starting structure for the present specification.

FIG. 8 depicts a cross-sectional view of the substrate of FIG. 7.

FIG. 9 and FIG. 9A represent elements and steps in connection with arranging the Channel Dielectric (“CD”).

FIG. 10, FIG. 10A, FIG. 10B, FIG. 10D and FIG. 10E represent elements and steps in connection with arranging the Charge Storage Region (“CSR”).

FIG. 11, FIG. 11A, FIG. 11B, FIG. 11C, FIG. 11D and FIG. 11E represent elements and steps in connection with arranging the Retention Dielectric (“RD”).

FIG. 12, FIG. 12A, FIG. 12B, FIG. 12C, FIG. 12D and FIG. 12E represent elements and steps in connection with arranging the Ballistic Gate (“BG”).

FIG. 13, FIG. 13A, FIG. 13B, FIG. 13C, FIG. 13D and FIG. 13E represent elements and steps in connection with arranging oxides in trenches adjacent memory cell elements.

FIG. 14A, FIG. 14B, FIG. 14C, FIG. 14D and FIG. 14E represent elements and steps in connection with arranging the Blocking Dielectric (“BD”).

FIG. 15A, FIG. 15B, FIG. 15C, FIG. 15D and FIG. 15E represent elements and steps in connection with arranging the Tunnel Gate (“TG”) conductor.

FIG. 15F represents elements and steps in connection with arranging embedded CMOS logic.

FIG. 16F represents elements and steps in connection with further arranging embedded CMOS logic.

FIG. 17F represents elements and steps in connection with further arranging embedded CMOS logic.

FIG. 18F represent elements and steps in connection with further arranging embedded CMOS logic.

FIG. 19, FIG. 19A, FIG. 19B, FIG. 19C, FIG. 19D, FIG. 19E and FIG. 19F represent elements and steps in connection with arranging Tunneling-gate (“TG”) lines.

FIG. 20, FIG. 20A, FIG. 20B, FIG. 20C, FIG. 20D, FIG. 20E and FIG. 20F represent elements and steps in connection with introducing strain.

FIG. 21, FIG. 21A, FIG. 21B, FIG. 21C, FIG. 21D, FIG. 21E and FIG. 21F represent elements and steps in connection with further processing.

FIG. 22, FIG. 22A, FIG. 22B, FIG. 22C, FIG. 22D, FIG. 22E and FIG. 22F represent elements and steps in connection with further processing.

FIG. 23, FIG. 23A, FIG. 23B, FIG. 23C, FIG. 23D, FIG. 23E and FIG. 23F represent elements and steps in connection with arranging self-aligned contact (SAC) holes.

FIG. 24, FIG. 24A, FIG. 24B, FIG. 24C, FIG. 24D, FIG. 24E and FIG. 24F represent elements and steps in connection with arranging Borderless Contact Holes.

FIG. 25, FIG. 25A, FIG. 25B, FIG. 25C, FIG. 25D, FIG. 25E and FIG. 25F represent elements and steps in connection with completing the integrated circuit (“IC”) structure.

FIG. 26F represent elements and steps in connection with alternate processing starting from the structure in FIG. 17F.

FIG. 27, FIG. 27A, FIG. 27B, FIG. 27C, FIG. 27D, FIG. 27E and FIG. 27F represent elements and steps in connection with further alternate processing.

FIG. 28, FIG. 28A, FIG. 28B, FIG. 28C, FIG. 28D, FIG. 28E and FIG. 28F represent elements and steps in connection with further alternate processing.

FIG. 29, FIG. 29A, FIG. 29B, FIG. 29C, FIG. 29D, FIG. 29E and FIG. 29F represent elements and steps in connection with further alternate processing.

FIG. 30, FIG. 30C, and FIG. 30F represent elements and steps in connection with arranging Borderless Contact Holes.

### DETAILED DESCRIPTION

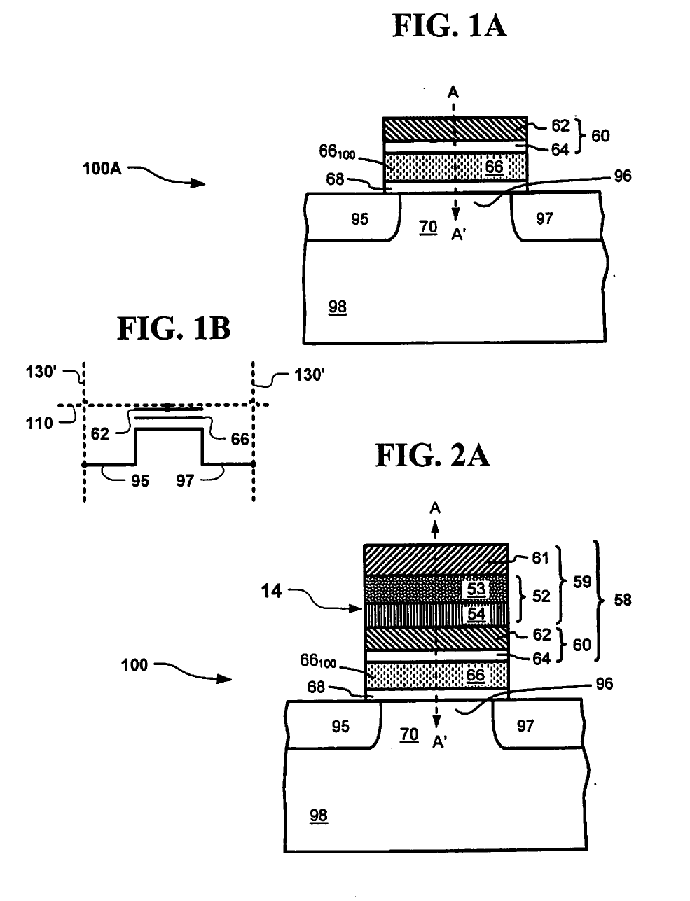

In FIG. 1A, a cross-sectional view of one embodiment of a cell structure including a memory cell 100A to be arranged in accordance with embodiments of the present specification is shown.

In this specification including the claims, different layers, regions, materials and other elements are described as deposited, etched, implanted, formed or otherwise arranged and such descriptions are intended to include all different manners of arranging such elements.

Referring to cell 100A of FIG. 1A, there is shown a charge storage region (“CSR”) 66. The charge storage region 66 includes a floating gate (“FG”) 66₁₀₀, and a channel dielectric (“CD”) 68. A conductor-insulator system 60 comprises a ballistic gate (“BG”) 62 and a retention dielectric (“RD”) 64 as the conductor and insulator of the system, respectively. The BG 62 is disposed adjacent to and insulated from the FG 66₁₀₀ by the retention dielectric (RD 64). The FG 66₁₀₀ is disposed adjacent to and insulated from the body 70 by CD 68. The FG 66₁₀₀ is typically encapsulated and insulated by dielectrics such as RD 64, CD 68, or other dielectrics in close proximity having proper thickness and good insulation property to retain charges thereon without leaking. Typically, RD 64 and CD 68 have the thicknesses in the range from about 5 nm to about 20 nm.

Cell 100A of FIG. 1A further provides a source 95, a channel 96, a drain 97, and a body 70 in a semiconductor substrate 98 (such as a silicon substrate or a silicon-on-insulator substrate). The body 70 comprises a semiconductor material of a first conductivity type (e.g. p-type) having doping level in the range from about 1×10¹⁵ atoms/cm³ to about 1×10¹⁸ atoms/cm³. The source 95 and drain 97 are arranged in the body 70 with the channel 96 of the body defined there between, and are typically heavily doped by impurity of a second conductivity type (e.g. n-type) having doping level in the range of about 1×10¹⁸ atoms/cm³ to about 5×10²¹ atoms/cm³. These doping regions may be arranged by thermal diffusion or by ion implantation. In this specification, the source 95 and drain 97 regions are interchangeable and hence any reference to a “source” can be interchanged with reference to a “drain” and vice versa. Because of this interchangeability, a source or a drain region is referred to as a source/drain region, a drain/source region, a first region or a second region.

The channel dielectric 68 is somewhat longer than the channel 96 so as to project over end portions of the source 95 and the drain 97.

In FIG. 1A, the FG 66₁₀₀ is for collecting and storing charge carriers and is polysilicon, poly SiGe or any other types of semiconductor materials that can effectively store charges. The conductivity of FG 66₁₀₀ is an n-type or a p-type. Materials for BG 62 is from the group comprising a semiconductor, such as n+ polysilicon, p+ polysilicon, heavily-doped poly SiGe etc, or a metal, such as aluminum (Al), platinum (Pt), Au, Tungsten (W), Molybdenum (Mo), ruthenium (Ru), tantalum (Ta), nickel (Ni), tantalum nitride (TaN), titanium nitride (TiN) etc, or alloy thereof, such as tungsten-silicide, nickel-silicide etc. While BG in cell 100A is shown in a single layer, BG 62 may comprise more than one layer. The thickness of BG 62 is in the range from about 20 nm to about 200 nm.

FIG. 1B depicts a schematic representation of the cell 100A of FIG. 1A. Where used in this specification, the FIG. 1B schematic represents cells of the cell 100A type.

The architecture of the cell 100A of FIG. 1A is described in the above identified cross-referenced application US 2006/0001053. The cross-referenced application discloses memory cells and arrays of the cell 100A type and further arranged using electrically alterable conductor-material systems. For purposes of the present specification including the claims, an electrically alterable conductor-material system is a system or element including a conductor having charge carriers with an energy distribution and including a material having an interface with the conductor with potential barriers in proximity to the interface where the potential barriers are electrically alterable to control transport of the charge carriers. The contents of the above-identified cross-referenced application US 2006/0001053 is hereby incorporated by reference in its entirety into this specification for incorporating the disclosure of memory cells, arrays and related information therein into the present specification.

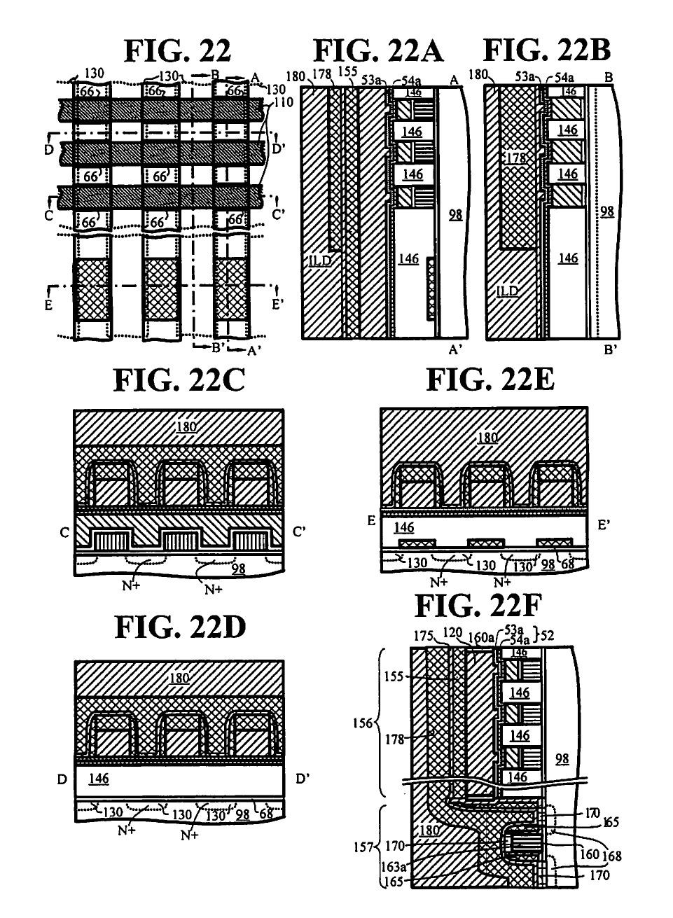

In the cross-referenced application US 2006/0001053, the conductor-material systems include a conductor-filter system, referring to FIG. 22 therein, arranged with a conductor that supplies thermal charge carriers with a filter contacting the conductor. The filter includes dielectrics for providing a filtering function on the charge carriers of one polarity, wherein the filter includes electrically alterable potential barriers for controlling flow of the charge carriers of one polarity through the filter in one direction. In addition to controlling the one polarity of charge carriers, the filter further includes another set of electrically alterable potential barriers for controlling the flow of charge carriers of an opposite polarity through the filter in another direction that is substantially opposite to the one direction.

In the cross-referenced application US 2006/0001053, the conductor-material systems include a conductor-insulator system comprising a conductor having energized charge carriers with an energy distribution and an insulator contacting the conductor at an interface. The insulator has an Image-Force potential barrier adjacent to the interface where the Image-Force potential barrier is electrically alterable to permit the energized charge carriers to transport there over.

In the cross-referenced application US 2006/0001053, the conductor-material systems include a charge-injection system comprising a conductor-filter system having a conductor for supplying thermal charge carriers and a filter contacting the conductor and including dielectrics for providing a filtering function on the charge carriers. The filter includes one set of electrically alterable potential barriers for controlling flow of the charge carriers of one polarity through the filter in one direction, and further includes another set of electrically alterable potential barriers for controlling flow of charge carriers of an opposite polarity through the filter in another direction that is substantially opposite to the one direction. The charge-injection system further comprises a conductor-insulator system. The conductor-insulator system includes a second conductor contacting the filter and having energized charge carriers from the filter, and an insulator contacting the second conductor at an interface and having an Image-Force potential barrier adjacent to the interface. The Image-Force potential barrier is electrically alterable to permit the energized charge carriers transporting there over.

The foregoing conductor-material systems used in memory cells are arranged in arrays in first and second directions with spaces between cells in each direction, that is, the cells have first direction and second direction cell pitches (P). In order to increase the cell density, it is desirable that the cell pitches be made small. Historically, the industry has tended over time to reduce the cell pitches for memory cells and arrays. Each of the cells in an array has interconnecting cell lines arranged in at least first and second directions such that cell lines cross over in the array. The naming of cell lines (word lines, tunneling lines, bit lines or other lines) and the number of the first lines and of the second lines in any particular direction are a matter of design convenience and, in general, the names, numbers and directions may be selected to satisfy any particular architecture desired.

Frequently, memory devices include related circuits including timing, sensing and logic (generally referred to as “embedded logic”) on the same substrate and it is desirable that the elements and steps for arranging the memory cells also be used for arranging the related logic and other embedded logic. References to logic in this specification, including the claims, also are referred to as logic transistors, embedded logic, logic circuits, Logic CMOS and other non-memory cell terms. In general, “logic” and “embedded logic” refers to components and methods relating to logical functions and other functions distinguished from components and methods relating to the memory functions of memory cells.

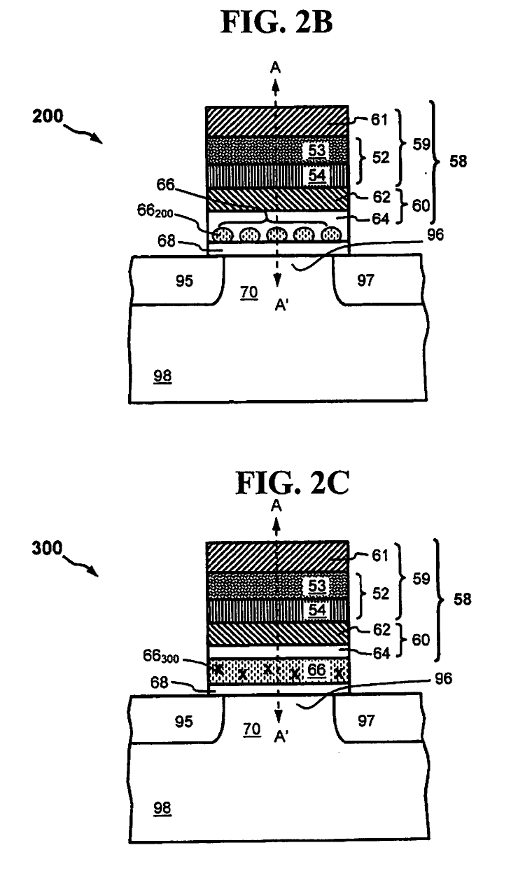

FIG. 2A depicts a cross-sectional view of one embodiment of a cell structure including a memory cell 100 to be arranged in accordance with embodiments of the present specification. Memory cells, like the cell 100, include one or more electrically alterable conductor-material systems 58 to control the transport of carriers. For purposes of the present specification including the claims, an electrically alterable conductor-material system is a system (that is, a group of elements) including a conductor having charge carriers with an energy distribution and including a material having an interface with the conductor with potential barriers in proximity to the interface where the potential barriers are electrically alterable to control transport of the charge carriers.

In this specification including the claims, different layers, regions, materials and other elements are described as deposited, etched, implanted, formed or otherwise arranged and such descriptions are intended to include all different manners of arranging such elements.

FIG. 2A shows a cross-sectional view of a cell 100 in accordance with one embodiment of the cross-referenced application US 2006/0001053. Referring to cell 100 of FIG. 2A, there is shown an electrically alterable system 58 including a conductor-filter system 59 and a conductor-insulator system 60. The system 58 is in proximity to the charge storage region (“CSR”) 66. The charge storage region 66 includes a floating gate (“FG”) 66₁₀₀, and a channel dielectric (“CD”) 68. FIG. 2A depicts the system 58 symmetrically aligned with the charge storage region 66. Such alignment, however, is only illustrative since the system 58 need only be in proximity to the charge storage region 66 such that transport of the charge carriers can be controlled.

The conductor-filter system 59 comprises a tunneling-gate (“TG”) 61, and a filter 52, wherein TG 61 corresponds to the conductor of the system 59. The filter 52 provides the band-pass filtering function, the charge-filtering function, the voltage divider function, and the mass-filtering function. In one embodiment, the filter 52 comprises a tunneling dielectric (“TD”) 53 and a blocking dielectric (“BD”) 54. The conductor-insulator system 60 comprises a ballistic gate (“BG”) 62 and a retention dielectric (“RD”) 64 as the conductor and insulator of the system, respectively. The cell structure in regions from TG 61 to RD 64 is constructed by “contacting” the filter 52 of the conductor-filter system 59 to the conductor (BG 62) of the conductor-insulator system 60. The structure thus arranged has TD 53 sandwiched in between the TG 61 and the BD 54 regions, and has BD 54 sandwiched in between the TD 53 and the BG 62 regions. The BG 62 is disposed adjacent to and insulated from the FG 66₁₀₀ by the retention dielectric (RD 64). The FG 66₁₀₀ is disposed adjacent to and insulated from the body 70 by CD 68. The FG 66₁₀₀ is typically encapsulated and insulated by dielectrics such as RD 64, CD 68, or other dielectrics in close proximity having proper thickness and good insulation property to retain charges thereon without leaking. Typically, RD 64 and CD 68 have the thicknesses in the range from about 5 nm to about 20 nm. TD 53 and BD 54 can comprise dielectrics having a uniform chemical element or a graded composition on its element. TD 53 and BD 54 is dielectric materials from the group comprising oxide, nitride, oxynitride, aluminum oxide (“A₂O₃”), hafnium oxide (“HfO₂”), zirconium oxide (“ZrO₂”), tantalum pen-oxide (“Ta₂O₅”). Furthermore, any composition of those materials and the alloys formed thereof, such as hafnium oxide-oxide alloy (“HfO₂—SiO₂”), hafnium-aluminum-oxide alloy (“HfAlO”), hafnium-oxynitride alloy (“HfSiON”) etc. is used as dielectric materials for TD and BD. In the embodiment, an oxide dielectric having thickness from 2 nm to 4 nm and a nitride dielectric having thickness ranging from about 2 nm to 5 nm are chosen for TD 53 and BD 54, respectively.

Cell 100 of FIG. 2A further provides a source 95, a channel 96, a drain 97, and a body 70 in a semiconductor substrate 98 (such as a silicon substrate or a silicon-on-insulator substrate). The body 70 comprises a semiconductor material of a first conductivity type (e.g. p-type) having doping level in the range from about 1×10¹⁵ atoms/cm³ to about 1×10⁸ atoms/cm³. The source 95 and drain 97 are arranged in the body 70 with the channel 96 of the body defined there between, and are typically heavily doped by impurity of a second conductivity type (e.g. n-type) having doping level in the range of about 1×10⁸ atoms/cm³ to about 5×10²¹ atoms/cm³. These doping regions may be arranged by thermal diffusion or by ion implantation. In this specification, the source 95 and drain 97 regions are interchangeable and hence, in general, any reference to a “source” can be interchanged with reference to a “drain” and vice versa.

The channel dielectric 68 is somewhat longer than the channel 96 so as to project over end portions of the source 95 and the drain 97.

In FIG. 2A, the TG 61 is shown overlapping the BG 62 to form an overlap portion between the two, where at least a portion of FG 66₁₀₀ is disposed there under. The overlap portion is essential in the cell structure as supplied charge carriers are filtered through that portion in order to be transported through BG 62, RD 64 and finally into the FG 66₁₀₀. The FG 66₁₀₀ is for collecting and storing such charge carriers and is polysilicon, poly SiGe or any other types of semiconductor materials that can effectively store charges. The conductivity of FG 66₁₀₀ is an n-type or a p-type. Materials for TG 61 and BG 62 is from the group comprising a semiconductor, such as n+ polysilicon, p+ polysilicon, heavily-doped poly SiGe etc, or a metal, such as aluminum (Al), platinum (Pt), Au, Tungsten (W), Molybdenum (Mo), ruthenium (Ru), tantalum (Ta), nickel (Ni), tantalum nitride (TaN), titanium nitride (TiN) etc, or alloy thereof, such as tungsten-silicide, nickel-silicide etc. While TG and BG in cell 100 are shown each in a single layer, BG 62 and TG 61 may comprise more than one layer in their respective architecture. For example, TG 61 can comprise a nickel-silicide layer arranged atop of a polysilicon layer to form a composite layer for TG 61. The thickness of TG 61 is in the range from about 80 nm to about 500 nm, and the thickness of BG 62 is in the range from about 20 nm to about 200 nm.

The program operation of memory cell 100 is done by employing the ballistic-electron injection mechanism or the piezo-ballistic-electron injection mechanism. These injection mechanisms inject energized charge carriers having energy distribution with an energy spectrum in the range of about 30 meV to about 300 meV onto CSR 66. For the specific embodiment, voltage of TG 61 is chosen in the range of about −3.3 V to about −4.5 V relative to voltage of BG 62 to form a voltage drop there between for injecting electrons having tight energy distribution. This is done, for example, by applying a −3.3 V voltage to TG 61 and a 0 V voltage to BG 62 to generate the −3.3 V voltage drop across TG and BG. Alternately, it is done by applying other voltage combinations, such as −1.8 V to TG and +1.5 V to BG. The voltage drop across TG and BG is further lowered by lowering the Image-Force barrier height of the conductor-insulator system 60. This is done by coupling a voltage in the range of about 1 V to about 3 V to CSR 66 through applying voltages in the range of about 1 V to about 3.3 V to source 95, drain 97, and body 70. For example, assuming 8 nm for the thickness of RD, such Image-Force lowering effect can reduce the −3.3 V voltage drop across TG and BG to a range of about −2.8 V to about −3.0 V.

The FG 66₁₀₀ of CSR 66 is negatively charged with electron carriers after the cell 100 is programmed to a program state. The programmed state of cell 100 is erased by performing an erase operation. The erase operation is done by employing the ballistic-hole injection mechanism or the piezo-ballistic-hole injection mechanism. These injection mechanisms inject energized charge carriers having energy distribution with an energy spectrum in the range of about 30 meV to about 300 meV onto CSR 66. For the specific embodiment, voltage of TG 61 is chosen in the range of about +5 V to about +6 V relative to voltage of BG 62 to form a voltage drop there between for injecting light-holes having tight energy distribution. This is done, for example, by applying a +3 V voltage to TG 61 and a −2 V voltage to BG 62 to generate the +5 V voltage drop across TG and BG. Alternately, it is done by applying other voltage combinations, such as +2.5 V to TG and −2.5 V to BG. The voltage drop across TG and BG is further lowered by lowering the Image-Force barrier height of the conductor-insulator system 60. The Image-Force barrier is somewhat lowered by FG 66₁₀₀ when it is negatively charged, and is generally further lowered by coupling a voltage in the range of about −1 V to about −3 V to CSR 66 through applying voltages in the range of about −1 V to about −3.3 V to source 95, drain 97, and body 70. For example, assuming 8 nm for the thickness of RD, such Image-Force lowering effect can reduce the +5 V voltage drop across TG and BG to a range of about +4.5 V to about +4.7 V.

Finally, to read the memory cell, a read voltage of approximately +1 V is applied to its drain 97 and approximately +2.5 V (depending upon the power supply voltage of the device) is applied to its BG 62. Other regions (i.e. source 95 and body 70) are at ground potential. If the FG 66₁₀₀ is positively charged (i.e. CSR 66 is discharged of electrons), then the channel 96 is turned on. Thus, an electrical current will flow from the source 95 to the drain 97. For an single-bit per cell storage scheme, the current thus read along with the bias thus applied would be the “1” state. On the other hand, if the FG 66₁₀₀ is negatively charged, the channel 96 is either weakly turned on or is entirely shut off. Even when BG 62 and drain 97 are raised to the read voltage, little or no current will flow through channel 96. In this case, either the current is very small compared to that of the “1” state or there is no current at all. In this manner, the memory cell is sensed to be programmed at the “0” state. Such read method is for illustration purpose and can be readily modified to other storage schemes such as multi-bits per cell scheme, wherein more than one bit is stored in one single cell.

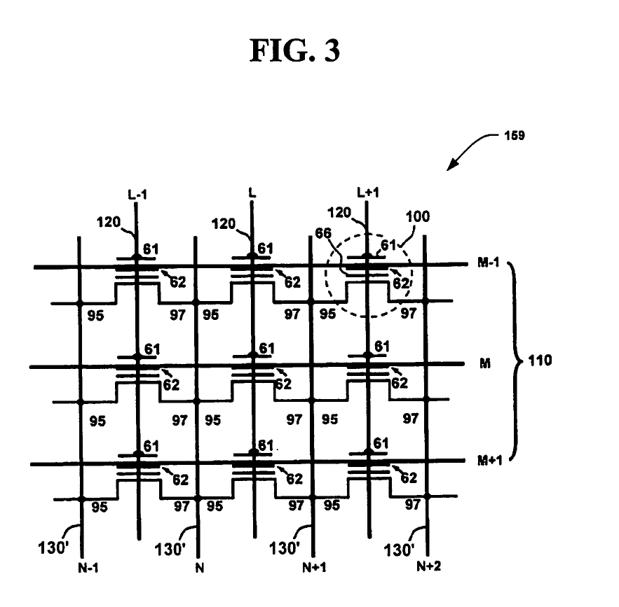

The memory cell 100 is illustrated in storing charges on CSR 66 of a conductive or semiconductor material (i.e. FG 66₁₀₀) that is electrically insulated from but capacitively coupled to surrounding conductive regions. In such a storage scheme, charges are evenly distributed through out CSR 66. However, it should be apparent to those of ordinary skill in the art that this disclosure is not limited to the particular embodiments illustrated herein and described above, but can encompass any other type of schemes for storing charges. For example, memory cells can store charges in CSR comprising a plurality of discrete storage sites such as nano-particles or traps in a dielectric layer, as illustrated in FIGS. 2 and 3, respectively.

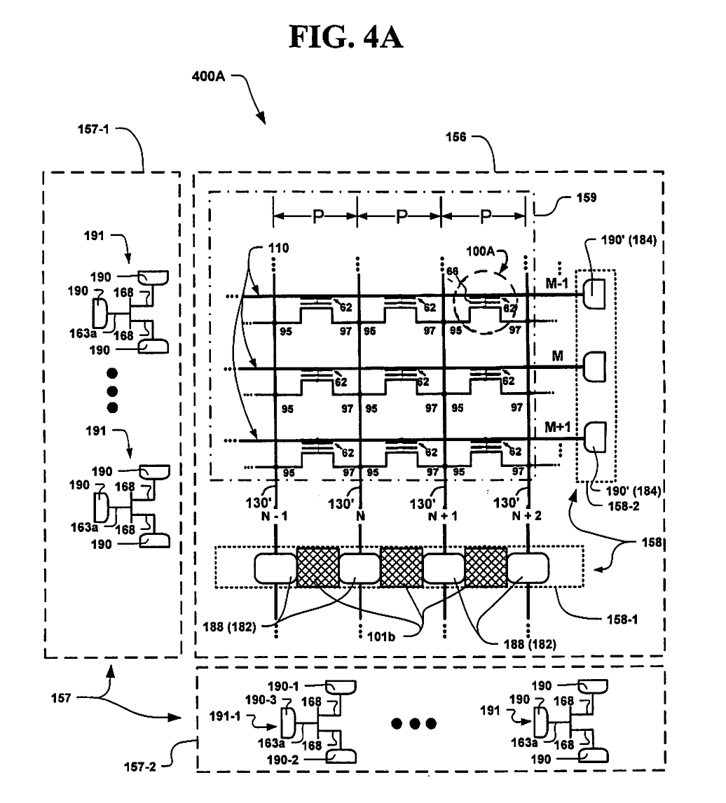

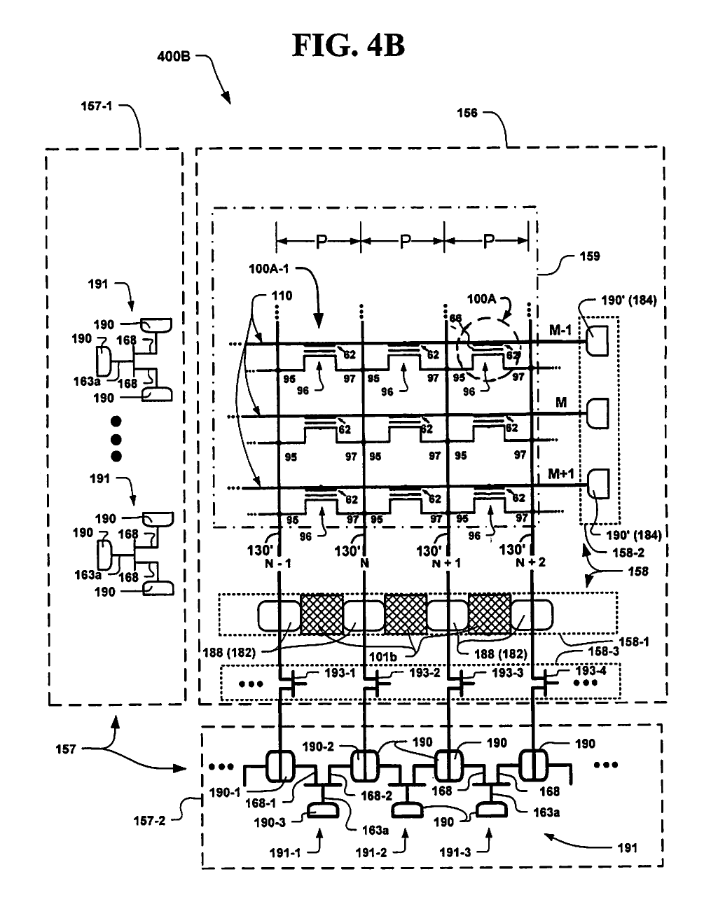

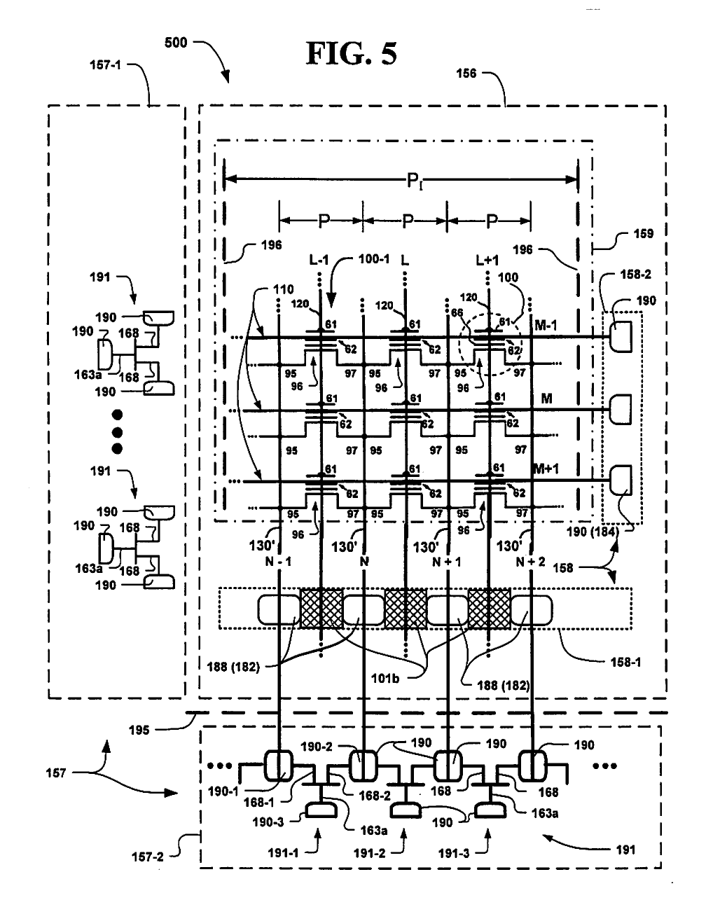

In FIG. 2A, the memory cell 100 is typical for use in a memory region (see FIG. 4 and FIG. 5) where each memory cell is to be arranged on a common substrate and wherein, for each memory cell, the source, the drain and the channel extend to a surface of the substrate, wherein the channel dielectric is adjacent the surface at the channel and wherein the charge storage region and electrically alterable conductor-material system are stacked in proximity to the channel dielectric.

FIG. 2B depicts a cross-sectional view of a memory cell 200 to be arranged in accordance with another embodiment employing nano-particles. In FIG. 2B, the cell 200 is a variation of the cell 100 of FIG. 2A.

The cell 200 is like cell 100 of FIG. 2A except that instead of a conductive region of FG 66₁₀₀ as CSR 66, the memory cell 200 is provided with a plurality of spaced-apart nano-particles 66₂₀₀ formed in nanometer scale as CSR 66. The nano-particles 66₂₀₀ are typically in an oval shape having a dimension in the range of about 2 nm to about 10 nm, and are shown contacting CD 68 and arranged in RD 64. The RD 64 is shown in a single layer and is a layer of a stack of different dielectrics, such as a layer of oxide/nitride/oxide stack. The nano-particles as the storage sites are silicon nano-crystals each in an oval shape having a diameter in the range of about 2 nm to about 7 nm, and are arranged by using well-known CVD techniques. The nano-particles is other types of semiconductor materials (e.g. Ge, SiGe alloy etc.), dielectric particles (e.g. HfO₂), or metals (e.g. Au, Ag, Pt etc.) that are in nano-particles form and can effectively store charges.

It should understood that the nano-particles 66₂₀₀ need not be in an oval shape in their cross section, need not be co-planar with the substrate surface, but rather is at any level under or above the substrate surface, and with other shapes that can effectively store charge carriers. Moreover, the nano-particles 66₂₀₀ need not be contacting the RD 64, need not be fully in the RD 64, but rather can be partially in RD 64 and partially in CD 68, or fully in CD 68.

FIG. 2C depicts a cross-sectional view of a memory cell 300 to be arranged in accordance with another embodiment employing traps in a dielectric layer. The cell 300 is like memory cell 100 of FIG. 2A except that instead of a conductive region for CSR 66, the cell 300 provides a CSR 66 of trapping dielectric having a plurality of trapping centers (traps 66₃₀₀). The dielectric CSR 66 uses traps 66₃₀₀ as the charge storage sites and is a nitride layer arranged, for example, by using LPCVD (Low-Pressure-Chemical-Vapor-Deposition) techniques well-known in the art. Other dielectrics such as HfO₂ and ZrO₂ having traps of a deeper trapping energy can also be used as material for the trapping dielectric.

Both memory cells 200 and 300 in FIG. 2B and FIG. 2C utilize schemes storing charges in localized charge storage sites that are in the form of nano-particles 66₂₀₀ and traps 66₃₀₀, respectively. These cells are operated in a similar way as that illustrated for cell 100 in connection with FIG. 2A. The advantages of the cell 200 and cell 300 structures are reduced process complexity, and a negligible interference between adjacent cells when such cells are arranged in a memory array. Furthermore, in the event there is a local breakdown in surrounding insulators of one of the sites, charges stored at other sites can still be retained to preserve logic data stored thereon.

The dimensions of the cells are closely related to the design rules of a given generation of process technology. Therefore, the dimensions on cells and on regions defined therein are only illustrative examples. In general, however, the dimension of the memory cells must be such that supplied charges are filtered and transported through the filter at a higher absolute voltage between TG and BG (e.g. 3 V to 6 V) and blocked by the filter at a lower absolute voltage (e.g. 2.5 V or lower). Furthermore, the dimensions of the BG and RD must be such that a large portion of filtered charges are allowed to transport through that region and be collected by the CSR at an injection efficiency typically ranging from about 10⁻⁶ to about 10⁻¹.

It is to be understood that the embodiments illustrated herein and described above are only by way of example and other variations may be employed.

FIG. 3 depicts a schematic diagram showing a memory cell region 159. The memory cells, where memory cell 100 of FIG. 2A is typical, are arranged in an array architecture in the memory cell region 159.

The memory cells of FIG. 3 are typically arranged in a rectangular array of rows and columns, wherein a plurality of cells are constructed in NOR or NAND logical function architecture well-known in the art. FIG. 3 illustrates a NOR array architecture in schematic diagram with illustration made using the memory cell 100 of FIG. 2A. Of course, other cells such as cell 200 of FIG. 2B and cell 300 of FIG. 2C can be employed and other logical function architectures can be employed.

Referring to FIG. 3, there are shown first cell lines 110 (for example, word lines), oriented in a first direction (for example, row direction). In the example described, the first cell lines 110 include lines M−1, M, and M+1. Further, there are shown second cell lines (for example, tunneling lines and bit lines) oriented in a second direction (for example, column direction). In the example described, the second cell lines include tunneling lines 120, namely tunneling lines L−1, L, and L+1, and include bit-lines 130′, namely N−1, N, N+1, and N+2.

The naming of cell lines (word lines, tunneling lines, bit lines or other lines) and the numbers of the first lines and of the second lines in any particular direction are a matter of design convenience and, in general, the names, numbers and directions can be selected to satisfy any particular architecture desired.

A ballistic gate (“BG”) 62 of each of the memory cells 100 in the same row are electrically coupled by one of the first lines 110. Thereby, the line M+1 connects BG 62 of each of the memory cells in the lowermost row. Each of the tunneling lines 120 connects all the TG 61 of memory cells in the same column. Thereby, the tunneling-line L−1 connects TG 61 of each of the memory cells in the leftmost column of FIG. 3. Likewise, each of the bit-lines 130′ connects all the drains 97 of memory cells in the same column. Thereby, the bit-line N connects the drain 97 of each of the memory cells in the leftmost column of FIG. 3. Since the array demonstrated in this example uses a virtual ground array architecture, the bit-line N for memory cells on the leftmost column also functioned as the source-line N for memory cells of an adjacent column (i.e. the center column of FIG. 3). Those of skill in the art will recognize that the term source and drain may be interchanged, and the source-lines and drain-lines or source-lines and bit-lines may be interchanged. Further, the word-line is electrically coupled to BG 62 of the memory cell. Thus, the term BG line may also be used interchangeably with the term word-line.

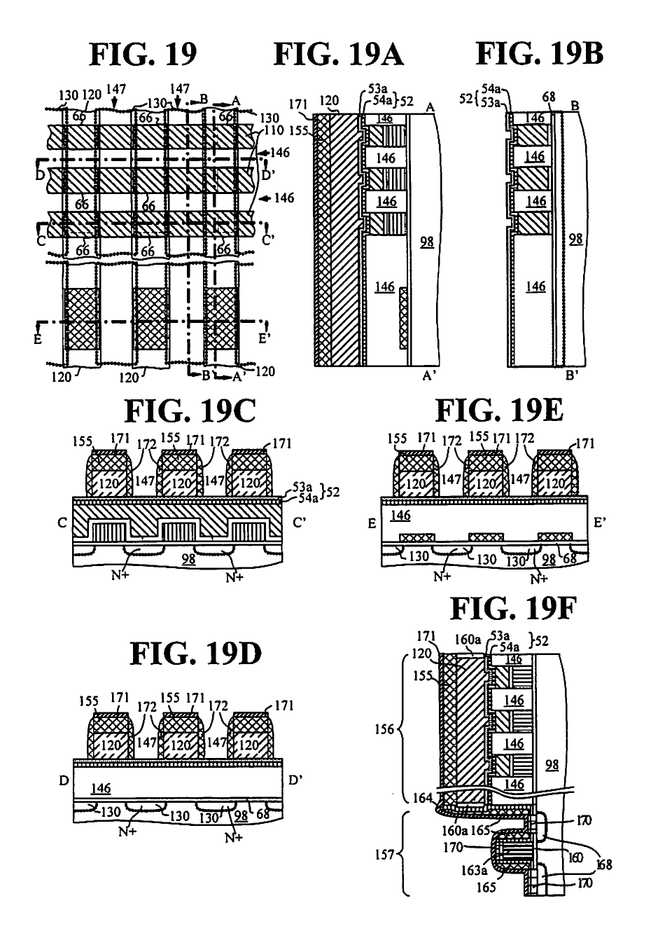

The cell lines 110, 120 and 130′ are formed using different processes. For example, the cell lines 130′ (bit-lines) are formed in one embodiment as a diffusion (see diffusion 130 in FIG. 19, for example), in other embodiments as a metal line or in additional embodiments can be both diffusion and metal lines as long as the diffusion and metal lines electrically couple the sources of the memory cells in the same column. For another example, the cell lines 110 (word lines) are formed in one embodiment as a poly, in other embodiments as metal lines or in additional embodiments can be both poly and metal lines as long as the poly and metal lines electrically couple the ballistic gates of the memory cells in the same rows. For an additional example, the cell lines 120 (tunneling lines) are formed in one embodiment as a poly, in other embodiments as metal lines or in additional embodiments can be both poly and metal lines as long as the poly and metal lines electrically couple the tunneling-gates of the memory cells in the same columns.

The NOR array shown in FIG. 3 is a well-known array architecture used as an example to illustrate the array formation using memory cells of the present specification. It should be appreciated that while only a small segment of an array is shown, the example in FIG. 3 illustrates any size of array of such regions. Additionally, the memory cells of the present embodiments are applied to other types of NOR array architectures. For example, while each of the bit lines 130′ is arranged to share with cells on an adjacent column as a source line, a memory array is arranged with cells on each column having their own dedicated source line. Furthermore, although the present specification is illustrated in a single cell and in a NOR array, it should be apparent to those of ordinary skill in the art that a plurality of cells of the present specification is arranged in a rectangular array of rows and columns, wherein the plurality of cells are constructed in NAND array architecture well-known in the art or a combination of a NAND and a NOR array structure.

For the memory cells described, it should be noted that both program and erase operations are performed with absolute bias at a level less than or equal to 3.3V. Furthermore, the erase mechanism and cell architecture enable the individually erasable cells feature, which is ideal for storing data such as constants that require periodic change. The same feature is further extendable to small groups of such cells which are erased simultaneously (e.g. cells storing a digital word, which typically contains 8 cells). Additionally, the same feature is also further extendable to such cells which are erasable simultaneously in large groups (e.g. cells storing code for software programs, which typically can contain 2048 cells configured in a page, or can contain a plurality of pages in block or array architectures).

In FIG. 4A, the memory device 400A is shown in schematic detail. The memory device 400A includes the memory region 156 that is further formed of the memory cell region 159 and the connection region 158 adjacent the memory cell region 159. The memory device 400A also includes the non-memory regions 157, including regions 157-1 and 157-2, adjacent the memory region 156. The memory device 400A is typically formed on a semiconductor substrate (see 98 in FIG. 1A). The cell 100A, as shown in FIG. 1A, is typical of the cells in the memory array 400A. The memory device 400A is shown for purposes of representation to include three rows and three columns of cells 100A. Of course, arrays are typically larger and typically include rows and columns with 4, 8, 16, 32, 64, 128, 256, 512 and generally 2^{N} rows or columns of cells where N is any integer. The number of rows need not equal the number of columns.

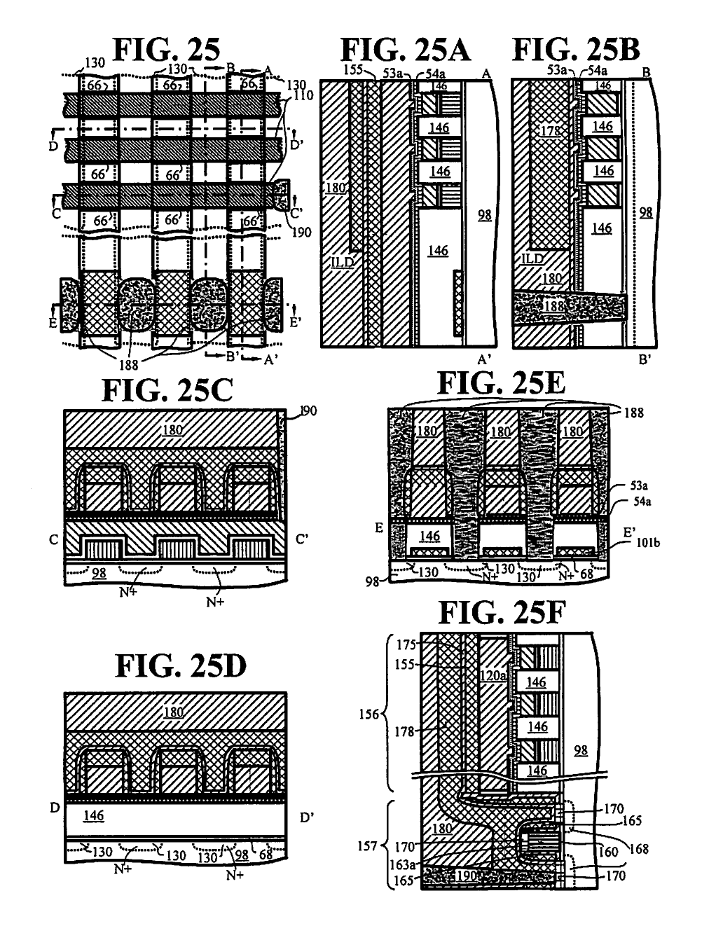

The density of the cells and the pitch (P) of the cells 100A and cell lines (110 and 130′) in the memory cell region 159 in FIG. 4A is in part controlled by the ability to make connections or otherwise electrically couple to the plurality of cell lines (110 and 130′) in the connection region 158 without requiring greater dimensions for the connections than are required for the other parts of the cells. The term “electrically couple” means to form a relationship between elements that are situated and configured such that an electrical voltage, current, field or other electrical phenomena is coupled between the elements. Electrical coupling occurs when elements such as first cell lines 130′ (bit-lines) and embedded logic 191 are coupled without an intermediary element (that is with direct contacting) or with a conductive intermediary element. The conductive intermediary element is selected from the group consisting of contacts (for example, contacts 188), diffusions (for example, diffusions 130 in FIG. 19), metal lines (such as metal lines described in connection with FIG. 25) and transistors (for example, transistors 191-1, 191-2, 191-3, . . . or transistors 193-1, 193-2, 193-3, 193-4, . . . of FIG. 4B) and combinations thereof.

In FIG. 4A, the connection region 158 is part of the memory region 156 and is adjacent the memory cell region 159. The connection region 158, including connection regions 158-1 and 158-2, is used for connection to any cell lines such as the cell lines 110, 120 and 130′. For example, the connection region 158-1 includes contacts 188, shown schematically electrically coupled to the lines 130′. The contacts 188 are formed in holes 182 between pairs of insulators 101b. The insulators 101b are typically arranged concurrently with the cell elements of the cells in the memory cell region 159 and hence are readily aligned substantially in alignment with the cell lines 130′. In a typical embodiment the self-aligned contact contacts (SAC) 188 are formed in holes 182 using self-aligned contact (SAC) elements and steps. Accordingly, the pitch (P) of the contacts 188 in certain embodiments matches the pitch (P) of the cells in the memory region 156 and similarly, the contact insulators 101b while offset from the cell lines 130′ are arrayed substantially in alignment with the cell lines 130′. Elements that are spaced apart with a repeating separation are defined as having the pitch (P) and are defined to be “arrayed at the cell pitch”. Accordingly, in FIG. 4A, the cells 100A, the cell lines 130′, the holes 182, the contacts 188 and the contact insulators 101b are all arrayed at the cell pitch. Also, the contact holes 182 are arranged substantially in alignment with the cell lines 130′.

The cell lines (110, 120,130) have been shown for simplicity as straight lines, but in general, cell lines can be rounded, bent, turned, staggered, zigzagged or otherwise arrayed in a repeating pattern where the “pitch” is some dimension related to the repetition of the pattern.

In the FIG. 4A device 400A, the contact insulators 101b are one or more materials selected from the group consisting of oxide, nitride, oxynitride and alloys thereof

The term “self-aligned” means contacts and contact holes that extend through layers of a semiconductor device with an arrangement of the materials and layers of the semiconductor device such that the holes and contacts are preferentially constrained to alignment at desired locations. For example, in the device 400A of FIG. 4A, the contacts 188 and holes 182 are “self-aligned” because the contacts 188 are formed in the holes 182 between pairs of insulators 101b where the insulators 101b, formed for example by nitride material, tend to constrain the holes 182 (and hence the contacts 188 in the holes 182) in the desired aligned location between the insulators 101b and thereby to be substantially aligned with the cell lines 130′.

In FIG. 4A, the cell lines 130′ are first cell lines (bit-lines) that in one embodiment extend into the connection region 158-1 and electrically couple the contacts 188. In an alternate embodiment, the cell lines 130′ terminate prior to and do not extend into the connection region 158-1. In such alternate embodiment, a transistor or other electrically coupling means (such as transistors 193 in FIG. 4B) has one terminal electrically coupled to the cell line 130′ and another terminal electrically coupled in the connection region 158-1, for example to a contact 188, whereby the cell line 130′ is electrically coupled into the connection region 158-1 without extending into the connection region 158-1.

The contacts 188 are formed substantially between pairs of the contact insulators 101b. The contacts 188 need not be symmetrically located with respect to the contact insulators 101b. A contact 188 may be closer to or offset from a particular one of the pair of contact insulators 101b relative to the other one of the pair of contact insulators 101b. Nonetheless, the locations of the contact insulators 101b is deemed to be substantially in alignment with the cell lines 130′ even though offsets are or may be present.

The connection region 158-2 includes contacts 190′, shown schematically to be electrically coupled to the M−1, M and M+1 lines 110 which are typical of many such cell lines when greater numbers of rows of memory cells are present. The contacts 190 in some embodiments are formed using borderless contact elements and steps and are typically used in locations where the dimensions are not as critical as for the self-aligned contacts 188.

The term “borderless” means contacts and contact holes that extend through layers of a semiconductor device where the arrangement of the materials and layers of the semiconductor device do not preferentially constrain the locations of contact holes and the contacts. For example, in the device 400A of FIG. 4A, the contacts 190′ and holes 184 are “borderless” because the arrangement of the materials and layers of the semiconductor device are such that the holes and contacts are not preferentially constrained.

In the FIG. 4A device 400A, a plurality of contacts 188, 190 and 190′ and contact holes 188 and 184 are employed wherein the contacts are selected from the group consisting of self-aligned contacts (188), borderless contacts (190) and combinations thereof.

FIG. 4A is schematic and the actual shape of the contacts 188 and 190 can be rectangular, round or any other shape, regular or irregular.

In FIG. 4A, the non-memory regions 157 are adjacent the memory region 156. The non-memory regions 157 include non-memory elements such as timing circuits, sense amplifiers and many other types of circuits. The transistors 191 (also identified as connection elements 191) are shown as representative examples and include contacts 190 at the gate 163a and the source and/or drain 168. In the FIG. 4A example, the transistors 191 are at locations that are generally independent of the array layout of the cells in the memory region 156. Typically, the contacts 190 are formed using borderless contact elements and steps that do not have as high a resolution as the contacts 188 formed using the self-aligned contact (SAC) elements and steps.

In FIG. 4A, the non-memory regions 157 include embedded logic 191 including a plurality of transistors, each transistor having three terminals 168. The terminals 168 include, for example, a first terminal that is a source, a second terminal that is a drain and third terminal that is a gate. Each of the terminals 168 is electrically coupled to a contact 190. The transistors of the embedded logic 191 are connected in many different ways. For example, transistors have one or more terminals electrically coupled to one or more cell lines and have one or more terminals electrically coupled to the terminals of other transistors of embedded logic 191. In FIG. 4A, at least one transistor terminal 168 in the non-memory region is electrically coupled to a first cell line 130′. In FIG. 4A, the embedded logic 191 in non-memory region 157-2 includes one or more transistors each having transistor terminals 168 wherein at least one of the transistor terminals is electrically coupled to at least one of the cell lines 130′. The cell lines 130′ are diffusions (for example, diffusions 130 in FIG. 19) or metal lines (such as metal lines described in connection with FIG. 25). For such electrical coupling, one or more of the first cell lines 130′ (for example, N−1 cell line 130′) extends (not shown in FIG. 4A, see FIG. 4B) into the non-memory region 157-2 and, by way of example, electrically couples to a contact 190-1 for a transistor 191-1.

The memory device of 400A of FIG. 4A includes another connection region 158-2 including another plurality of contacts 190′ (in holes 184) wherein one or more of the plurality of cell lines (110,130′) of memory device 400A extend into the connection region 158-2 for electrically coupling to one or more of the another plurality of contacts 190′. For example, the M−1, M and M+1 cell lines 110 extend into the region 158-2.

In FIG. 4B, the memory device 400B is shown in schematic detail. The memory device 400B is like the memory device 4A and includes the memory region 156 that is further formed of the memory cell region 159 and the connection region 158, including connection regions 158-1, 158-2 and 158-3 adjacent the memory cell region 159. The memory device 400B also includes the non-memory regions 157, including regions 157-1 and 157-2, adjacent the memory region 156. The memory device 400B is typically formed on a semiconductor substrate (see 98 in FIG. 1A). The cell 100A, as schematically shown in FIG. 1B, is typical of the cells in the memory array 400A. The memory device 400B is shown for purposes of representation to include three rows and three columns of cells 100A. Of course, arrays are typically larger and typically include rows and columns with 4, 8, 16, 32, 64, 128, 256, 512 and generally 2^{N} rows or columns of cells where N is any integer. The number of rows need not equal the number of columns.

In FIG. 4B, a plurality of cell lines 110 and 130′ includes first cell lines 130′ extending into the connection region 158-1, wherein the connection region 158-1 includes a plurality of contact insulators 101b, each of the contact insulators aligned substantially between pairs of the first cell lines (for example, between the pair N−1 and N, the pair N and N+1 and the pair N+1 and N+2), and wherein each of the contacts 188 is arranged substantially between pairs of the contact insulators. In FIG. 4B, the contact region contacts 188 are arrayed at the cell pitch (P) in the contact region 158-1 and one or more of the contacts 188 electrically couples to one or more of the first cell lines 130′. Electrical coupling of contacts 188 to more than one cell line 130′ occurs, for example, in the non-memory region 157-2 by the transistors 191-1, 191-2, 191-3 and so on. Also, the connection region 158-3 includes transistors 193 (for example, 193-1, 193-2, 193-3 and 194-4, . . . ), typically arrayed at the cell pitch, P. The transistors 193 are source/drain inline with the cell lines 130′. Each transistor 193 includes terminals connected respectively to a source, a drain and a gate whereby when the gate is enabled, the source/drain electrically couples the cell line 130′ to the non-memory region 157. For example, the transistor 193-1 couples to one of the cell lines, the N−1 cell line 130′, and the transistor 193-2 couples to another one of the cell lines, the N cell line 130′.

In FIG. 4B, the cell lines 130′ are first cell lines (bit-lines) that in one embodiment extend into the connection region 158-1 and electrically couple the contacts 188. In an alternate embodiment, the cell lines 130′ terminate prior to and do not extend into the connection region 158-1. In such alternate embodiment, a transistor or other electrically coupling means has one terminal electrically coupled to the a cell line 130′ and another terminal electrically coupled in the contact region 158-1, for example to a contact 188, whereby the cell line 130′ is electrically coupled into the connection region 158-1 without extending into the connection region 158-1.

In the memory device of FIG. 4B, the non-memory region 157-2 has, from the plurality of cell lines 110 and 130′, an extension of first cell lines 130′ wherein the non-memory region includes a plurality of non-memory region contacts (for example, contacts 190-1 and 190-2) each non-memory region contact connecting to one of the first cell lines 130′ (for example, 190-1 connecting to N−1 line 130′ and 190-2 connecting to N cell line 130′). In FIG. 4B, the non-memory region 157-2 includes embedded logic, for example, including a plurality of transistors 191. In FIG. 4B, the non-memory region 157-2 has embedded logic 191 and the plurality of cell lines (110, 130′) of memory device 400B includes one or more first cell lines 130′ extending into the non-memory region 157-2 for electrically coupling the embedded logic 191.

In FIG. 4B, the transistors 191 each have three terminals 168. The terminals 168 include, for example, a first terminal that is a source, a second terminal that is a drain and third terminal that is a gate. Each of the terminals 168 is electrically coupled to a contact 190. In particular, each transistor having a first terminal, for example a source 168-1 electrically coupled to a first cell line (for example, N−1 line 130′ electrically coupled to source 168-1 by contact 190-1), a second terminal, for example a drain connected to a first cell line (for example, N line 130′ electrically coupled to drain 168-2 by contact 190-2) and a gate connected to a non-memory region contact (for example, gate 163a electrically coupled to contact 190-3).

In FIG. 4B, elements in the non-memory region 157-2 are spaced apart with a repeating separation defined as the pitch (P) and hence, like elements in the memory region 159, are defined to be “arrayed at the cell pitch”. In FIG. 4B, the elements arrayed at the cell pitch include cells 100A, the cell lines 130′, the holes 182, the contacts 188, the contact insulators 101b, the non-memory contacts 190 and the transistors 191.

The memory device of 400B of FIG. 4B includes another connection region 158-2 including another plurality of contacts 190′ (in holes 184) wherein one or more of the plurality of cell lines (110,130′) of memory device 400B extend into the connection region 158-2 for electrically coupling to one or more of the another plurality of contacts 190′. For example, the M−1, M and M+1 cell lines 110 extend into the region 158-2 for electrically coupling to one or more of the another plurality of contacts 190′.

The memory device 400B of FIG. 4B includes, for one or more incidences, a first one of the transistors (191-1) having a first-transistor first terminal (168-1) electrically coupled to a first one of the cell lines (N−1), has a first-transistor second terminal (168-2) electrically coupled to a second one of the cell lines (N) and has a first-transistor gate (163a) whereby enabling the first-transistor gate electrically couples the first one of the cell lines (N−1) and the second one of the cell lines (N).

When repeated for a first and second of the one or more incidences, the memory device of 400B of FIG. 4B includes for the first incidence, a first one of the transistors (191-1) having a first-transistor first terminal (168-1) electrically coupled to a first one of the cell lines (N−1), has a first-transistor second terminal (168-2) electrically coupled to a second one of the cell lines (N) and has a first-transistor gate (163a) whereby enabling the first-transistor gate (163a) electrically couples the first one of the cell lines (N−1) and the second one of the cell lines (N). For the second incidence of the one or more incidences, a second one of the transistors (191-2) has a second-transistor first terminal connected to the second one of the cell lines (N), has a second-transistor second terminal connected to a third one of the cell lines (N+1) and has a second-transistor gate whereby enabling the second-transistor gate electrically couples the second one of the cell lines (N) and the third one of the cell lines (N+1).

In FIG. 5, the memory device 500 is shown in schematic detail and is substantially the same as the memory device 400A in FIG. 4A except the cells 100 are typically of the form of cell 100 in FIG. 2A having the additional L−1, L and L+1 cell lines 120. In the non-memory region 157-2 of FIG. 5, the embedded logic 191, including by way of example the transistors 191-1, 191-2 and 191-3 as typical, are arrayed at the cell pitch and are oriented and located according to the array layout of the cells 100 in the memory cell region 159. In particular, considering transistor 191-1 as typical, the contact 190-1 connecting to the first region source/drain terminal 168-1 of transistor 191-1 is aligned with the N−1 line 130′ that couples to first regions (sources 95) of a first column 100A-1 of cells 100A in memory cell region 159. Similarly, the contact 190-2 connecting to the second cell region drain/source 168-2 of transistor 191-1 is aligned with the N line 130′ that couples to second cell regions (drains 97) of the first column 100A-1 of cells 100A. The source 95 cell regions and the drain 97 cell regions are of course interchangeable and hence the first cell region in cells 100A may be either source or drain and the second cell regions may be either source or drain. The transistor 191-1 has a gate 163a coupled to contact 190-3 whereby transistor 191-1 causes the source-to-drain connection between source/drains 168-1 and 168-2, contacts 190-1 and 190-2 and N−1 line 130′ and N line 130′ to be coupled with a low impedance (short) or a high impedance (open). When the connection transistor 191-1 is controlled to be conducting, transistor 191-1 electrically couples the N−1 cell line 130′ to the N cell line 130′. The electrical coupling can be to any number of other cell lines by operation of the transistors 191-2, 191-3, . . . and so on where any number of additional transistors 191 (not shown) may be provided based upon the size of the memory device 500.

In FIG. 5, the cell lines 110, 120 and 130′ are formed using different processes. For example, the cell lines 130′ (bit-lines) are formed in one embodiment as a diffusion and in other embodiments as a metal line. The cell lines in general may extend from the memory cell region 159 into a connection region 158 and/or into a non-memory region 157. Typically, the cell lines 130′ are bit-lines that extend at least into the connection region 158.

In FIG. 5, the cell lines 130′ are first cell lines (bit-lines) that in one embodiment extend into the connection region 158-1 and electrically couple the contacts 188. In an alternate embodiment, the cell lines 130′ terminate prior to and do not extend into the connection region 158-1. In such alternate embodiment, a transistor or other electrically coupling means has one terminal electrically coupled to the a cell line 130′ and another terminal electrically coupled in the contact region 158-1, for example to a contact 188, whereby the cell line 130′ is electrically coupled into the connection region 158-1 without extending into the connection region 158-1.

In FIG. 5, the non-memory region 157-2 in FIG. 5 includes embedded logic 191 including a plurality of transistors 191 where each transistor (for example, transistor 191-1) is electrically coupled between a first contact (190-1) and a second contact (190-2) electrically coupled to first (N−1 line 130′) and second (N cell line 130′) cell lines 130′, respectively, whereby the transistor 191-1 electrically couples the contact 190-1 and first cell line (N−1 cell line 130′) to the contact 190-2 and second cell line (N cell line 130′). It still further apparent from the foregoing description that the memory device of FIG. 5 includes two or more transistors (for example, transistors 191-1 and 191-2) for electrically coupling three or more cell lines (for example, N−1, N and N+1 cell lines 130′). With this layout, the transistors embedded logic 191 has the transistors 191-1, 191-2 191-3, and so on, arrayed at the cell pitch (P).

It is apparent from FIG. 5, that a plurality of cell lines 110 and 130′ includes first cell lines 130′ extending into the connection region 158-1, wherein the connection region 158-1 includes a plurality of contact insulators 101b, each of the contact insulators aligned substantially between pairs of the first cell lines (for example, between the pair N−1 and N, the pair N and N+1 and the pair N+1 and N+2), and wherein each of the contacts 188 is arranged substantially between pairs of the contact insulators. In FIG. 5, the non-memory region contacts 188 are arrayed at the cell pitch (P) in the non-memory region 157-2 and one or more of the non-memory region contacts 188 is electrically coupling to one or more of the cell lines 130′. Electrical coupling of a contact such as contact 190-1 to more than one cell line 130′ occurs by enabling the transistors 191-1, 191-2, 191-3 and so on to be conducting. As described, the non-memory region 157-2 is an example of embedded logic including a plurality of transistors 191, including transistors 191-1, 191-2 and 191-3, where each transistor 191 has a transistor terminal 168 electrically coupled to at least one of the cell lines 130′.

FIG. 5, the memory device 500 is shown in schematic detail. The memory device 500 includes the memory region 156 that is further formed of the memory cell region 159 and the connection region 158 adjacent the memory cell region 159. The memory device 500 also includes the non-memory regions 157, including regions 157-1 and 157-2, adjacent the memory region 156. The memory device 500 is typically formed on a semiconductor substrate (see 98 in FIG. 2A). The cells 100 in FIG. 5 include all the elements of the cell 100 in FIG. 2A. The cells 100 in FIG. 5, therefore, differ from the cells 100A in FIG. 4A and in FIG. 4B in that the cells 100 additionally include, referring to FIG. 2A, a Conductor Filter system 59 including a Blocking Dielectric (“BD”) 54 and a Tunneling Dielectric (“TD”) 53 and a Tunneling-gate (“TG”) 61. Only the tunneling-gates 61 are shown explicitly in FIG. 5. The tunneling-gates 61 in FIG. 5 are electrically coupled in columns by the cell lines 120 where the L-1 cell line 120 for the column 100-1 is typical.

In FIG. 5, the memory device 500 in some embodiments employs a suitable isolation 195, such as a LOCOS isolation or a shallow-trench isolation (STI) well-known in the art, to define and isolate memory region 156 from the non-memory region 157. In some embodiments, isolation is not used in the memory region 156. In other embodiments, suitable isolation 196, such as LOCOS isolation or shallow-trench isolation (STI), is employed in the memory region 156. Typically, when isolation 196 is employed, the isolation 196 is not employed for every cell line (bit line) 130′. The memory device includes one or more isolations 195 and 196 located in the memory device between the memory and non-memory regions, between the memory cell region and the connection region or in any of the memory cell, connection or non-memory regions. The isolations 195 and 196 employ any suitable isolation scheme, such as LOCOS isolation or shallow-trench isolation (STI). In one embodiment, the cell lines 130′ are bit lines occurring at a bit-line pitch (P). Additionally, isolations 196 are located in the memory cell region 159 and extending in the direction of the cell lines 130′. In FIG. 5, the isolations 196 occur at an isolation pitch (P₁) where the isolation pitch (P₁) is greater than the bit-line pitch (P) so that there is not an isolation 196 for each bit line 130′. Isolation may occur in the bit cell line direction (such as isolations 196 in FIG. 5), in the word cell line direction (such as isolation 195 in FIG. 5). For any isolations, the pitch and the regions in which the isolations are located are all optional and are included, not included or varied as to location and pitch as may be warranted by particular embodiments and design needs. Although the isolations are shown in the memory device 500 of FIG. 5, the isolations similarly can be used in the arrays for the memory devices 400A and 400B of FIG. 4A and FIG. 4B.

The memory device of 500 of FIG. 5 includes another connection region 158-2 including another plurality of contacts 190′ (in holes 184) wherein one or more of the plurality of cell lines (110,130′) of memory device 500 extend into the connection region 158-2 for electrically coupling to one or more of the another plurality of contacts 190′. For example, the M−1, M and M+1 cell lines 110 extend into the region 158-2 for electrically coupling to one or more of the another plurality of contacts 190′.

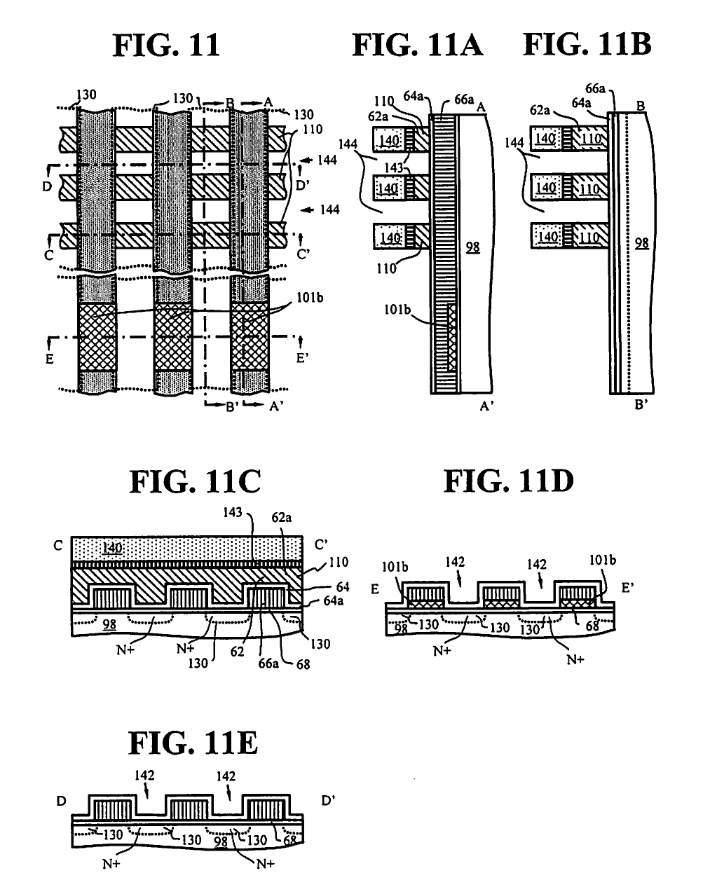

In FIG. 4A, FIG. 4B and/or FIG. 5, the terminals (for example, 168-1, 168-2) for a transistor (for example, transistor 191-1) connect in one embodiment described through contacts (for example, 190-1, 190-2) to cell lines (for example, N−1 line 130′ and N line 130′). In other embodiments, the terminals (for example, 168-1, 168-2) for a transistor (for example, 191-1) connect directly to cell lines (for example, N−1 line 130′ and N line 130′) by sharing the same diffusions without need for contacts (for example, 190-1, 190-2). The diffusion of the cell lines 130′ are described in connection with FIG. 11 and the diffusion of the terminals 168 are described in connection with FIG. 17F. These diffusions when extended into a common region directly connect the terminals (for example, 168-1, 168-2) for a transistor (for example, 191-1) directly to cell lines (for example, N−1 line 130′ and N line 130′) without need for any contacts.

The terminology and numbering in the present specification is substantially the same as in the cross-referenced application US 2006/0001053 and that application is hereby incorporated by reference in its entirety including definitions and examples of terms similarly used in the present specification.

In particular, the present application and the cross-referenced application US 2006/0001053 include the following like-numbered elements in a cell, a Substrate (“SUB”) 98 having a Source (“S”) 95, Drain (“D”) 97, a Channel (“C”) 96, a body (B) 70, a Channel Dielectric (“CD”) 68, a Charge Storage region (“CSR”) 66, a Conductor-Insulator system 60 including a Retention Dielectric (“RD”) 64 and a Ballistic Gate (“BG”) 62, a Conductor Filter system 59 including a Blocking Dielectric (“BD”) 54, a Tunneling Dielectric (“TD”) 53 and a Tunneling-gate (“TG”) 61.

In a general sense, the memory device 100 (and analogously other memory devices such as memory devices 200 and 300 of FIG. 2B and FIG. 2C) is a semiconductor device comprising a first conductive region (61), a dielectric region (52), a second conductive region (62) disposed adjacent to and insulated from the first conductive region by the dielectric region, a third region (66) disposed adjacent to and insulated from the second conductive region, and a strain source (178) providing a mechanical stress to at least one of the first and the second conductive regions.

Of those common like-numbered elements, the Conductor Filter system 59 including the Blocking Dielectric (“BD”) 54 and the Tunneling Dielectric (“TD”) 53 and the Tunneling-gate (“TG”) 61 are added elements to the cell 100A of FIG. 1A to form the cell 100 of FIG. 2A. As described in the cross-referenced application US 2006/0001053, the Blocking Dielectric (“BD”) 54 preferably has an energy band gap narrower than that of Tunneling Dielectric (“TD”) 53. Further, Blocking Dielectric (“BD”) 54 preferably has a larger dielectric constant relative to that of Tunneling Dielectric (“TD”) 53, among other reasons, to reduce the electric field and enhance the blocking effect on electrons and to permit a larger portion of the applied voltage to appear across Tunneling Dielectric (“TD”) 53.

In a general sense, the memory device 100 (and analogously other memory devices such as memory devices 200 and 300 of FIG. 2B and FIG. 2C) is a semiconductor device comprising a first conductive region (61), a dielectric region (52), a second conductive region (62) disposed adjacent to and insulated from the first conductive region by the dielectric region, a third region (66) disposed adjacent to and insulated from the second conductive region, and a strain source (178) providing a mechanical stress to at least one of the first and the second conductive regions.

In an embodiment, the dielectric region includes a charge injection filter (52) disposed in between the first and the second conductive regions, wherein the charge injection filter permits transporting of charge carriers of one polarity type from the first conductive region through the second conductive region to the third region and blocks transporting of charge carriers of an opposite polarity type from the second conductive region to the first conductive region.

In an embodiment, the mechanical stress introduced by the strain source (178) is a tensile stress or a compressive stress. In an embodiment, the mechanical stress produces a strain along a direction substantially parallel to a direction of charge carriers transported in the second conductive region.

In an embodiment, the second conductive region comprises material selected from the group consisting of Pt, Au, W, Mo, Ru, Ta, TaN, TiN, silicide, n+ polysilicon, p+ polysilicon, n+ poly SiGe, porous silicon, and p+ poly SiGe.

In an embodiment, the strain source (178) comprises material selected from the group consisting of nitride, tungsten-silicide, amorphous silicon, poly SiGe, TaN, and TiN.

In an embodiment, the strain source (178) comprises dislocation loops in at least one of the first and the second conductive regions.

In an embodiment, the charge injection filter comprises a first dielectric (54) disposed adjacent to the second conductive region and a second dielectric (53) disposed adjacent to the first conductive region and wherein the first dielectric has an energy band gap narrower than an energy band gap of the second dielectric.

In an embodiment, a product of a dielectric constant of the first dielectric and a thickness of the second dielectric is greater than a product of a dielectric constant of the second dielectric and a thickness of the first dielectric.

In an embodiment, the second dielectric comprises oxide, and the first dielectric comprises material selected from the group consisting of nitride, oxynitride, Al₂O₃, H_{f}O₂, TiO₂, ZrO₂, Ta₂O₅, and alloys formed thereof.

In an embodiment, the second dielectric comprises oxynitride, and the first dielectric comprises material selected from the group consisting of nitride, Al₂O₃, H_{f}O₂, TiO₂, ZrO₂, Ta₂O₅, H_{f}O₂—SiO₂, and alloys formed thereof.

In an embodiment, the third region comprises material selected from the group consisting of conductive material, nano-particles, and dielectrics.

In a general sense, the memory device 100 (and analogously other memory devices such as memory devices 200 and 300 of FIG. 2B and FIG. 2C) is a semiconductor device further comprising a first conductive region (61) having charge carriers for ballistic transport, a second conductive region (62) disposed adjacent to and insulated from the first conductive region to control the ballistic transport of the charge carriers, a third region (66) disposed adjacent to and insulated from the second conductive region where the third region receives the charge carriers with an injection efficiency for the ballistic transport, and the strain source (178) generating mechanical stress in at least one of the first and second conductive regions to enhance the injection efficiency of the ballistic transport.

In an embodiment, the mechanical stress is generated by ion implantation where typically the ion implantation comprises implanting a chemical element selected from the group consisting of Ge, Si, As, and nitrogen.

In a general sense, the memory device 100 (and analogously other memory devices such as memory devices 200 and 300 of FIG. 2B and FIG. 2C) is a semiconductor device still further comprising a first conductive region (61) having a population of charge carriers, a second conductive region (62) disposed adjacent to and insulated from the first conductive region for controlling transport of charge carriers from the first conductive region where the charge carriers in the second conductive region have a mean-free-path, a third region (66)) disposed adjacent to and insulated from the second conductive region, the third region for receiving the charge carriers with an injection efficiency, a strain source (178) providing a mechanical stress in at least one of the first and second conductive regions to alter the injection efficiency.

In an embodiment, the population of charge carriers in the first conductive region is altered by the mechanical stress to enhance the injection efficiency.

In an embodiment, the mean-free-path in the second conductive region is increased by the mechanical stress to enhance the injection efficiency.

The density of the cells and the pitch (P) of the cells 100 and the cell lines (110, 120, 130′) in the memory cell region 159 in FIG. 5 is in part controlled by the ability to make connections to the cell lines (110, 120, 130′) in the connection region 158 without requiring greater dimensions for the connections than are required for the other parts of the cells. In FIG. 5, the connection region 158 is part of the memory region 156 and is adjacent the memory cell region 159. The connection region 158-1 includes contacts 188, shown schematically, coupled to the lines 130′. The contacts 188 are formed between pairs of insulators 101b. The insulators 101b are arranged concurrently with the cell elements of the cells in the memory cell region 159 and hence are readily aligned with the cell lines 130′. Accordingly, the pitch of the contacts 188 matches the pitch of the cells in the memory region 156. The connection region 158-2 includes contacts 190, shown schematically, coupled to the lines M−1, M and M+1 which are typical of many such cell lines when greater numbers of rows of memory bit cells are present. The contacts 188 are formed between pairs of the contact insulators 101b. The contacts 188 need not be symmetrically located with respect to the pair of contact insulators 101b or a particular one of the contact insulators. A contact 188 may be closer to or offset from a particular contact insulator 101b than the other. The contacts 188 may have irregular shapes. The insulators 101b are arranged concurrently with the cell elements of the cells in the memory cell region 159 and hence are readily aligned with the cell lines 130′. Accordingly, in the connection region 158-2, each contact 188 is located in proximity to a pair of the contact insulators 101b. While only one contact 188 can be located between a pair of the contact insulators 101b, additional one or more contacts 188 may be located between the same pair of the contact insulators 101b. The contact insulators 101b can be elongated or of different shapes relative to the size and shapes of the contacts 188 to facilitate the presence of multiple contacts 188 between pairs of contact insulators 101b.

FIG. 5 is schematic and the actual shape of the contacts 188 and 190 can be rectangular, round or any other shape, regular or irregular. The important feature is that pairs of the insulators 101b bracket the contacts 188 and hence the contacts 188 from being misaligned with the cell lines 130′. The insulators 101b are formed concurrently with the formation of the cell structures and hence are automatically aligned with the cell lines 130′. In a typical embodiment the contacts 188 are formed in self-aligned contact holes using self-aligned contact (SAC) elements and steps. Accordingly, the pitch of the contacts 188 in such embodiments matches the pitch of the cells in the memory region 156.

The contacts 188 are formed in contact holes 182 between pairs of the contact insulators 101b. The contacts 188 and contact holes 182 need not be symmetrically located with respect to the contact insulators 101b. A contact 188 and a contact hole 182 may be closer to or offset from a particular one of the pair of contact insulators 101b relative to the other one of the pair of contact insulators 101b. The contact holes formed using the self-aligned contact (SAC) steps provide insulators (see 172 in FIG. 24E) adjacent sides of the holes that prevent the contacts from shorting to conductive regions.

The connection region 158-2 includes contacts 190, shown schematically coupled to the lines M−1, M and M+1 which are typical of many such cell lines when greater numbers of rows of memory bit cells are present. The contacts 190 in some embodiments are formed using borderless contact elements and steps and are typically used in locations where the dimensions are not as critical as they are for the self-aligned contacts 188.

In FIG. 5, in non-memory region 157-2, the embedded logic 191, including the transistors 191-1, 191-2 and 191-3, are typical examples and are oriented and located according to the array layout of the cells 100 in the memory cell region 159. In particular, considering transistor 191-1 as typical, the contact 190-1 connecting to the first region source/drain 168-1 of transistor 191-1 is aligned with the N−1 line 130′ that couples to first regions (sources 95) of a first column 100-1 of cells 100 in memory cell region 159. Similarly, the contact 190-2 connecting to the second region drain/source 168-2 of transistor 191-1 is aligned with the N line 130′ that couples to second regions (drains 97) of the first column 100-1 of cells 100. The source 95 regions and the drain 97 regions are of course interchangeable and hence the first region in cells 100 may be either source or drain and the second regions may be either source or drain. The transistor 191-1 has a gate 163a coupled to contact 190-3 whereby transistor 191-1 causes the source-to-drain connection between source/drains 168-1 and 168-2, contacts 190-1 and 190-2 and N−1 line 130′ and N line 130′ to be coupled with a low impedance (short) or a high impedance (open) as a function of a control signal applied to gate 163a and contact 190-3. While the transistor 191-1, when controlled to be conducting, couples the N−1 cell line 130′ to the N cell line 130, the coupling can be to any number of other cell lines by operation of the transistors 191-2, 191-3, . . . and so on where any number of additional transistors 191 (not shown) may be provided based upon the size of the memory device 500.

In FIG. 4B and FIG. 5, memory devices (memory devices 400B and 500, respectively) are shown having a first region (memory region 156) having a plurality of memory cells (cell 100A and 100, respectively) including for each memory cell, a first cell region (source/drain 95), a second cell region (drain/source 97), a cell channel (96) between the first cell region and the second cell region and a charge storage region (66), a second region (non-memory region 157-2) having a plurality of transistors (191-1, 191-2, 191-3, . . . ) including for each transistor a first transistor terminal (terminal 168-1), a second transistor terminal (terminal 168-2), a transistor channel between the first transistor terminal and the second transistor terminal and a gate (62), a plurality of cell lines (130′) extending in the first region (memory region 156) and in the second region (non-memory region 157-2) where a first one of the cell lines (N−1 cell line 130′) electrically couples the first cell regions (sources 95) of first ones of the memory cells (the left column of memory cells 100-1) to a first one of the first transistor terminals (terminal 168-1 for transistor 191-1) and where a second one of the cell lines (N cell line 130′) electrically couples the second cell regions (drains 97) of the first ones of the memory cells (the left column of memory cells 100-1) to a second one of the first transistor terminals (168-2 for transistor 191-1). In the example described, the first one of the cell lines (N−1 cell line 130′) is adjacent the second one of the cell lines (N cell line 130′). Similarly, a first one of the cell lines (N cell line 130′) is adjacent a second one of the cell lines (N+1 cell line 130′) and a first one of the cell lines (N+1 cell line 130′) is adjacent a second one of the cell lines (N+2 cell line 130′).

While FIG. 5 has depicted with the non-memory region 157-2 for the memory device 500 like the non-memory region 157-2 for the memory device 400B of FIG. 4, in an alternate embodiment, the non-memory region 157-2 for the memory device 500 can have other forms such as the non-memory region 157-2 for the memory device 400A of FIG. 4A.

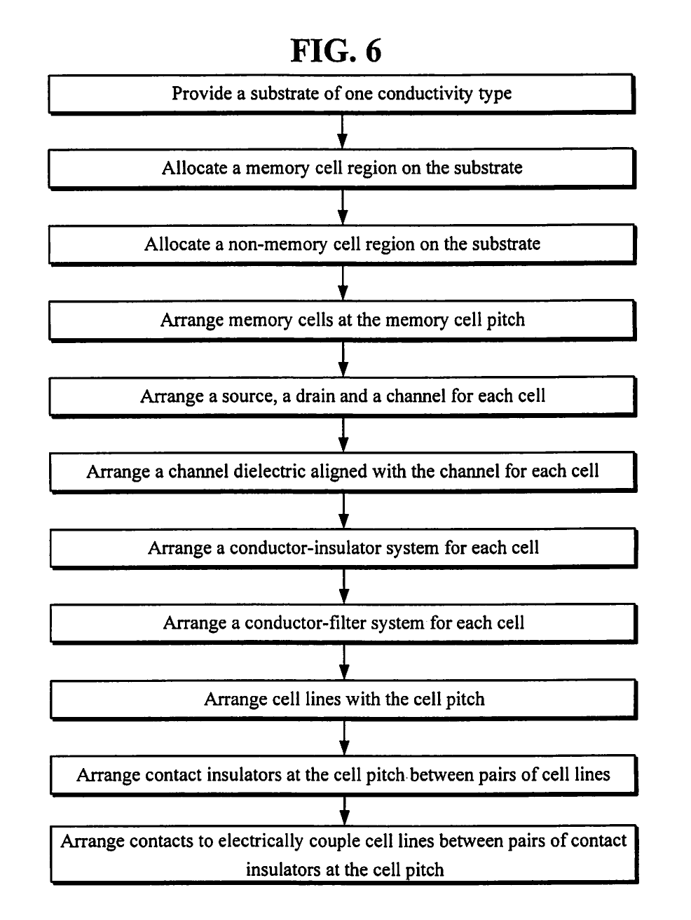

In FIG. 6, the generalized step sequence for arranging a cell structure in accordance with the present specification is shown. By way of examples, FIG. 4A depicts one memory device 400A, FIG. 4B depicts another memory device 400B and FIG. 5 depicts another memory device 500. These memory devices are manufactured by the generalized step sequence. The memory devices include many different types of memory cells such as the cells 100A, 100, 200 and 300 of FIG. 1A, FIG. 2A, FIG. 2B and FIG. 2C. The method operates to provide a substrate of one conductivity type, to allocate a memory cell region on the substrate, to allocate a non-memory region on the substrate, to arrange memory cells at the memory cell pitch, to arrange a source, a drain and a channel for each memory cell, to arrange a channel dielectric aligned with the channel, to arrange a conductor-insulator system, to arrange a conductor-filter system, to arrange cell lines with the cell pitch, to arrange contact insulators at the cell pitch bracketing cell lines and to arrange contacts to cell lines between contact insulators at the cell pitch.

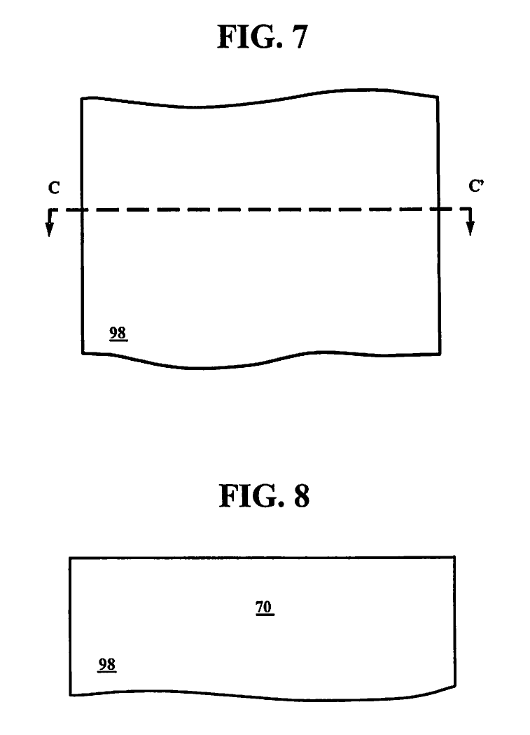

Referring to FIG. 7, one particular example of the generalized manufacturing method is described for the memory device 500 of FIG. 5. The method starts with a semiconductor substrate 98. The substrate 98 is used as the starting material for arranging memory cells, an array of memory cells, and logic transistors supporting memory operations. A cross-sectional view of the material thus described is shown in FIG. 8 wherein the substrate 98 is preferably a silicon of a first conductivity type (e.g. p-type). A body 70 is arranged in the substrate by well-known techniques such as ion implantation, and is assumed having the first conductivity type. The body 70 is isolated from the substrate 98 by semiconductor region having a second type of conductivity (e.g. deep n-type Well). A suitable isolation scheme, such as LOCOS isolation or shallow-trench isolation (STI) well-known in the art, is employed to define and isolate memory cell regions from non-memory regions (not shown in FIG. 8), such as peripheral regions typically used for timing circuits, sensing circuits and logic circuits supporting memory operations. In one embodiment, such isolation is not used in the memory region. In other embodiments, suitable isolation schemes, such as LOCOS isolation or shallow-trench isolation (STI) are employed in the memory region, including the memory cell region and/or the connection region, and/or are employed in the non-memory cell region.

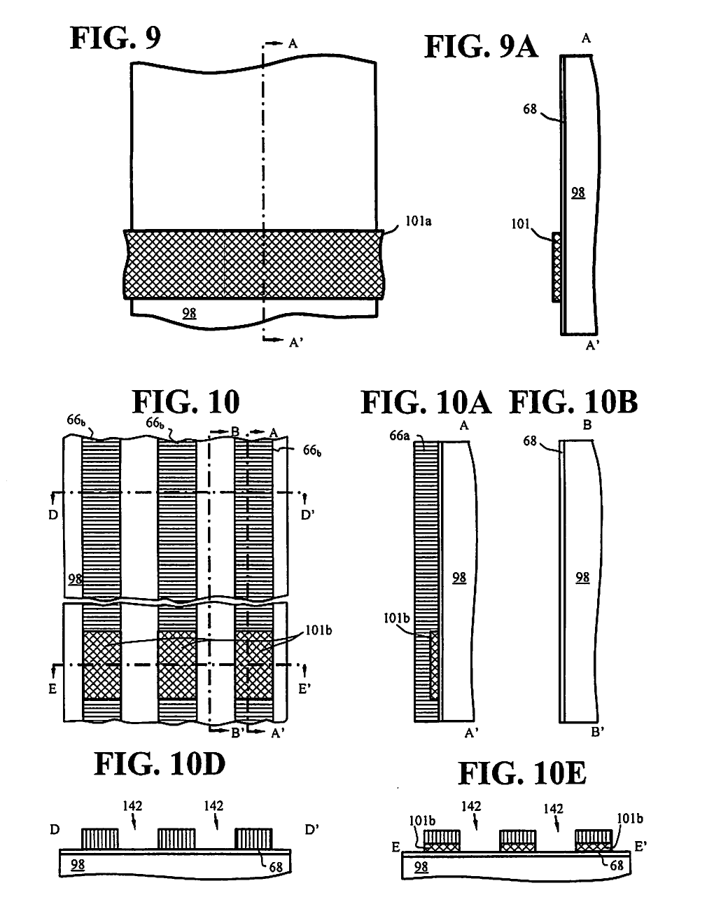

In FIG. 9 and FIG. 9A, the elements and steps of arranging a first insulator 68 over the substrate 98 and a nitride 101 on top of the first insulator 68 are depicted. In the embodiment described, the first insulator 68 has a thickness preferably in a range from of about 7 nm to about 9 nm. The insulator 68 is preferably made of oxide arranged by employing conventional thermal oxidation, HTO, or in-situ steam generation (“ISSG”) techniques well-known in the art.

The nitride 101 is arranged on top of the first insulator 68 using conventional LPCVD techniques. The thickness of the nitride is chosen such that it can withstand a contact etch that is used to etch away inter-layer-dielectrics “ILD” such as oxides. Typical nitride thicknesses are from 20 nm to 100 nm.

The detailed elements and steps of arranging the first insulator 68 over the substrate 98 and the nitride 101 are as follows. A photo-resistant material (“photo-resist” hereinafter) is arranged on the substrate 98 surface followed by a masking step using a conventional photo-lithography techniques to selectively remove the photo-resist so as to leave a plurality of photo-resist line traces oriented in a first direction (for example, a row direction) interspersed with exposed nitride.

The exposed nitride is etched until the insulator 68 is observed where the insulator 68 acts as an etch stop to the nitride etch. The portions of nitride still underneath the remaining photo-resist line traces are unaffected by this etch process. Therefore, this step arranges a plurality of nitride line traces oriented in the first direction (for example, row direction) of which line trace 101a is typical. Next, the photo-resist remaining over portions of the nitride are removed. The resulting structure (top view) and a cross-section along line AA′ are shown in FIG. 9 and FIG. 9A, respectively.

FIG. 10, FIG. 10A, FIG. 10B, FIG. 10D and FIG. 10E depict removal of the oxide in the exposed area, arranging oxide in the exposed area, arranging a layer of charge storage material, arranging a plurality of poly lines orientated in a second direction with each pair of poly lines spaced apart by first trenches to expose portions of nitride line traces in the first trenches and removal of the exposed portions of the nitride traces. These steps are performed as follows.

The oxide 68 in removed in the exposed area.

An oxide is arranged in the exposed area by employing thermal oxidation, HTO, or by ISSG techniques to reform the oxide layer 68. A layer of charge storage material 66a such as polysilicon is arranged over the structure using, for example, conventional LPCVD techniques with polysilicon film doped in situ or by a subsequent ion implantation step. The polysilicon layer 66a thus formed is used for arranging CSR 66 of the memory cell, and is doped with impurity of a second conductivity type at a doping level in the range of about 1×10¹⁸ atoms/cm³ to about 5×10²¹ atoms/cm³. The polysilicon layer 66a has a thickness, for example, in the range from about 40 nm to 50 nm. Preferably, the topography of the polysilicon layer 66a thus formed is substantially planar.

A plurality of poly lines 66b are arranged so as to be orientated in a second direction (for example, “column direction”) with each pair of lines spaced apart by a first trench 142 using a conventional photo-lithography, including a masking step, followed by a dry etching technique (e.g. RIE) removing the polysilicon layer 66a. The step exposes portions of the nitride line traces of which line 101a in the first trench 142 is typical.

The exposed portions of nitride traces 101a are removed by a dry etching technique to arrange a plurality of nitride elements 101b self-aligned to the poly lines 66b. The nitride elements 101b each provide protection for self-align contact formation on lines (for example, bit-lines) in later steps of the process. The resulting structure (top view) and a cross-section along lines AA′, BB′, DD′, and EE′ are shown in FIGS. 10, 10A, 10B, 10D and 10E, respectively.

FIG. 11, FIG. 11A, FIG. 11B, FIG. 11C, FIG. 11D and FIG. 11E depict performing an ion implantation step to dope the exposed silicon region in the second type of conductivity to arrange diffusion regions self-aligned to the first trench, arranging a second insulator layer over the exposed charge storage layer, arranging a layer of conductive material over the structure, arranging a dielectric over the conductive layer and arranging a plurality of lines orientated in the first direction with each pair of them spaced apart by a second trench. These steps are performed as follows.

An ion implantation step is performed to dope the exposed silicon region in the second type of conductivity material to arrange diffusion regions self-aligned to the first trench 142. Such diffusion regions form the lines 130 (diffusion lines 130 are one embodiment of the bit lines 130′). The remaining photo-resist is then removed using conventional techniques.

A second insulator layer 64a is arranged over the exposed charge storage layer 66a with a thickness preferably in the range from about 7 nm to about 9 nm. The insulator layer 64a is typically an oxide deposited by employing conventional HTO (preferred), thermal oxidation, TEOS or ISSG deposition techniques.

A layer of conductive material 62a such as polysilicon is arranged over the structure using, for example, conventional LPCVD techniques with polysilicon film doped in-situ or by a subsequent ion implantation step. Typically, the conductive material 62a has a thickness sufficient to fill the first trenches 142 and typically is in the range from about 30 nm to about 80 nm.

A dielectric 143 (e.g. nitride) is arranged over the conductive layer 62a with thickness preferably in the range from about 10 nm to about 50 nm.

A plurality of first lines 110 (for example, word lines) are orientated in the first direction (for example, “row direction”) with each pair of lines spaced apart by a second trench 144. This is typically done by arranging photo-resist traces 140 using a conventional photo-lithography and masking steps, followed by a dry etching technique (e.g. RIE). Each line connects the ballistic gate (BG) 62 of cells on the same row.

The resulting structure and a cross-section along lines AA′, BB′, CC′, DD′, and EE′ are shown in FIG. 11A, FIG. 11B, FIG. 11C, FIG. 11D and FIG. 11E, respectively.

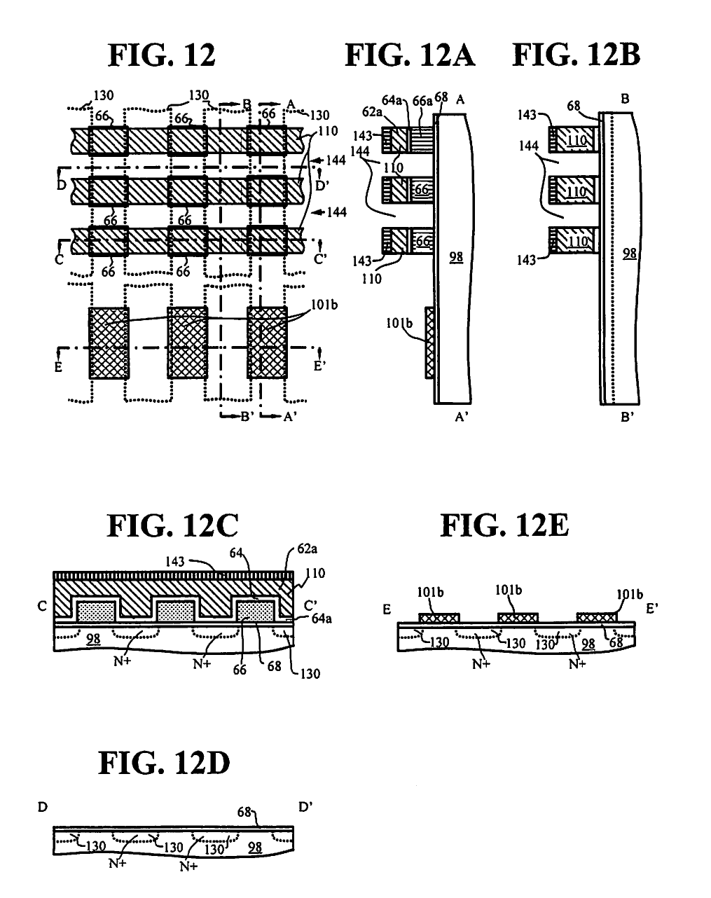

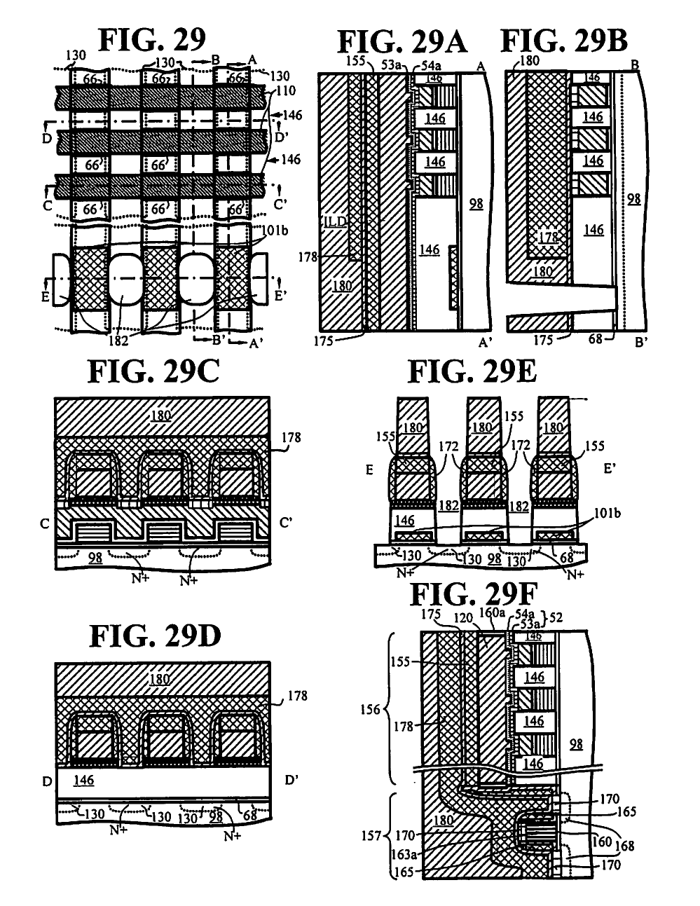

In FIG. 12, etching of the exposed second layer 64a occurs followed by etching the exposed charge storage layer 66a until the first insulator 68 is reached where insulator 68 acts as an etch stop. The portions of layer 66a underneath the remaining photo-resist are unaffected by this etch process. A plurality of CSR 66 are arranged and the nitride elements 101b are exposed. The remaining photo-resist is then removed using conventional means. The top plan view of the resulting structure is shown in FIG. 28 with lines line 110 (for example, word-lines) interlaced with the second trenches 144. The cross-sectional views along lines AA′, BB′, CC′, DD′ and EE′ of the resulting structure are collectively illustrated in FIGS. 12A, 12B, 12C, 12D and 12E, respectively.

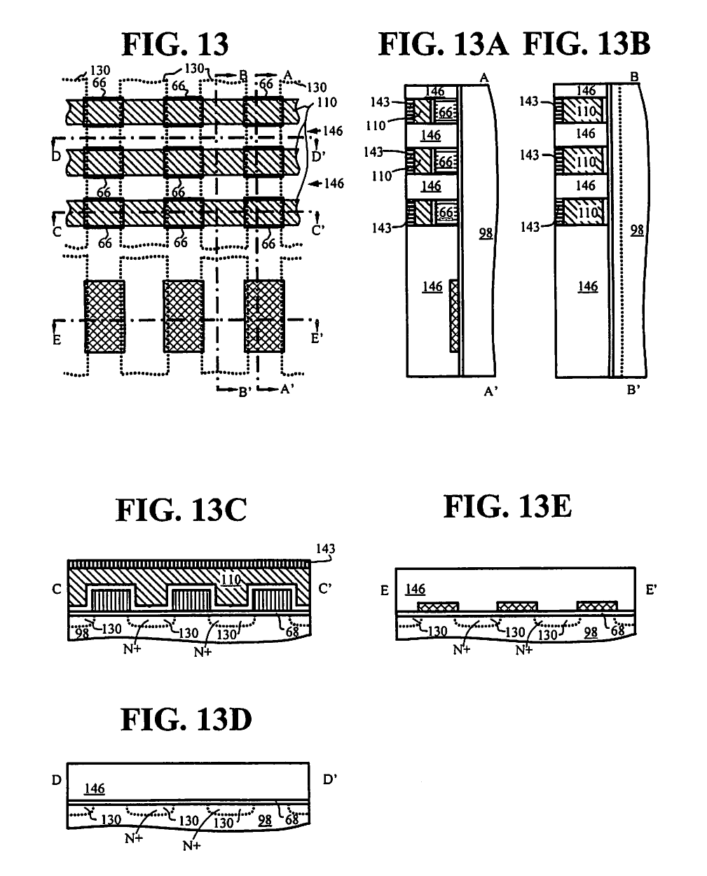

In FIG. 13, FIG. 13A, FIG. 13B, FIG. 13C, FIG. 13D and FIG. 13E, an insulating layer (not shown) is optionally arranged as an oxide on sidewalls of first lines 110 (for example, on word-lines) and CSR 66 exposed to the trench 144. The oxide is arranged, for example, by performing a thermal oxidation step using rapid-thermal-oxidation (RTO) technique, typically having a thickness in a range from about 2 nm to about 8 nm.

A thick dielectric layer (e.g. oxide) is arranged to fill the trenches 144 by using well-known techniques such as conventional LPCVD. The oxide dielectric is then selectively removed to leave oxide blocks 146 in the region within the trenches 144. The preferable structure is with the top surface of the oxide blocks 146 substantially co-planar with the top surface of the nitride dielectric 143. This structure is achieved, for example, by employing a chemical-mechanical polishing (CMP) process to planarize the thick oxide followed by an RIE (reactive ion etch) using nitride dielectric 143 as a polishing and/or etching stopper. An optional oxide over-etching step follows as needed to clear any oxide residue on the nitride dielectric 143. The process thereby leaves oxide only in trenches 144 to arrange oxide blocks 146 self-aligned to the trenches 144. The top plan view of the resulting structure is illustrated in FIG. 13 with first lines 110 (for example, word-lines) interlaced with the oxide line blocks 146. The cross-sectional views along lines AA′, BB′, CC′, DD′ and EE′ of the resulting structure are collectively illustrated in FIG. 13A, FIG. 13B, FIG. 13C, FIG. 13D and FIG. 13E, respectively.

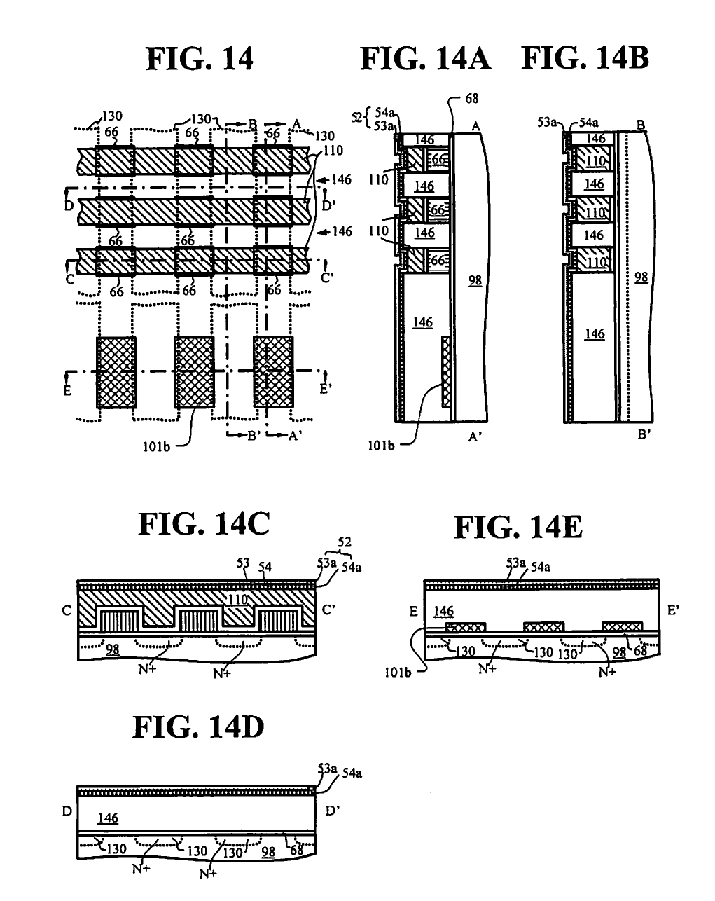

In FIG. 14A, FIG. 14B, FIG. 14C, FIG. 14D and FIG. 14E, the nitride dielectric 143 is removed by a conventional etching step (e.g. using hot phosphoric acid).

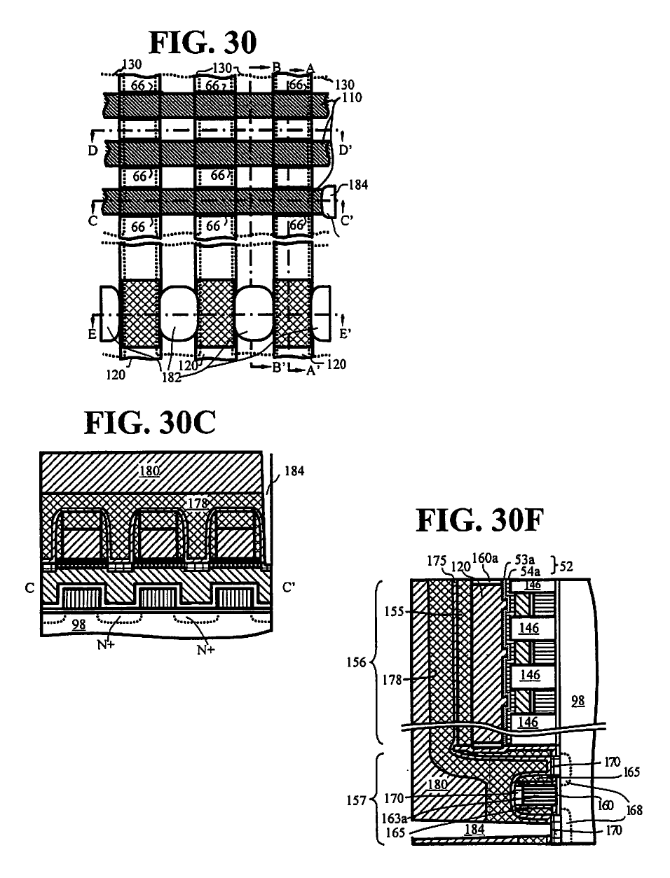

A filter 52 is arranged having multi-layer dielectrics over the first lines 110 (for example, word-lines). In a specific embodiment, a third insulator 54a (BD) and a fourth insulator 53a (TD) are the multi-layer dielectrics for the filter 52. The third insulator layer 54a, such as nitride, is arranged over the first lines 110 (for example, word-lines) by employing thermal nitridation such as rapid-thermal-nitridation (RTN) in NH₃ ambient at 1050 C. The third insulator 54a has a thickness preferably in the range from about 2 nm to about 5 nm. The process is continued by arranging the fourth insulator layer 53a such as oxide over the third insulator 54a. The fourth insulator is typically arranged by using thermal oxidation, HTO, TEOS, or ISSG techniques well-known in the art. The fourth insulator 53a has a thickness preferably in the range from about 2 nm to about 4 nm. The third and fourth insulator layers 54a and 53a are used as BD 54 and TD 53, respectively, of the memory cells. The top plan view of the resulting structure is illustrated in FIG. 30, and the cross-sectional views along lines AA′, BB′, CC′, DD′ and EE′ of the resulting structure are collectively illustrated in FIG. 14A, FIG. 14B, FIG. 14C, FIG. 14D and FIG. 14E, respectively.

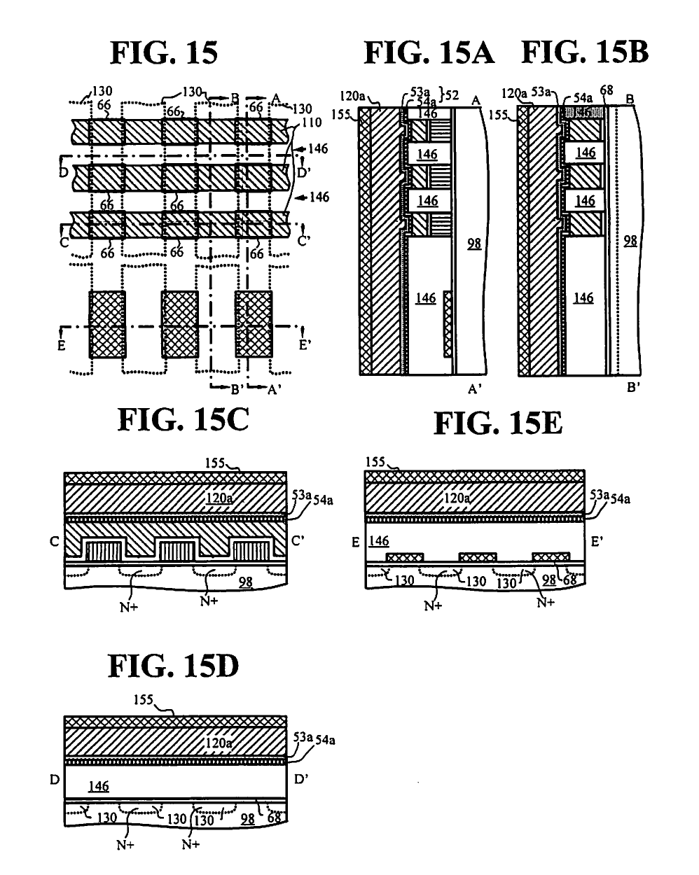

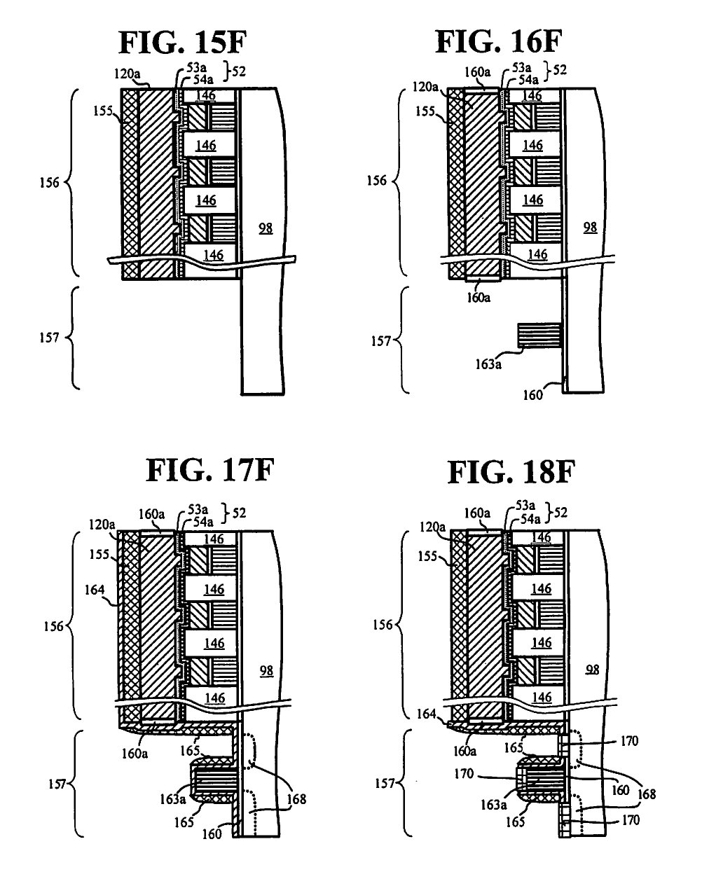

FIG. 15, FIG. 15A, FIG. 15B, FIG. 15C, FIG. 15D and FIG. 15E depict the self-aligned contact (SAC) etching-stop layer formation.

A conductor 120a is arranged on top of the filter 52 (including 53a & 54a) as the TG conductor. A p+ poly Si atop with a tungsten silicide is preferably chosen for the TG conductor. The thickness of the TG conductor is range from 0.05 um to 0.2 um pending on the technology node chosen. Typically, TG conductor thickness is thinner for more advanced technology nodes. For example, 70 nm (or 0.07 um) for the TG conductor is preferred for a 45 nm node technology.

A first thick nitride 155 is arranged on top of the TG conductor using conventional LPCVD techniques. The thickness of the first thick nitride 155 is chosen such that it can withstand a contact etch that is used to etch away inter-layer-dielectric “ILD” such as oxide. Typical nitride thicknesses range from about 20 nm to about 100 nm.

The resulting structure for FIG. 15 is shown with the cross-sections along lines AA′, BB′, CC′, DD′, and EE′ in FIG. 15A, FIG. 15B, FIG. 15C, FIG. 15D and FIG. 15E, respectively.

In FIG. 15F, the steps for embedding Logic CMOS in the non-memory region of the memory device are shown.

A photo-resist is arranged covering the memory cell region using a conventional photo-lithography and masking step. This step protects the first thick nitride 155 in the memory cells region 156 but exposes the first thick nitride 155 in non-memory regions 157, such as peripheral regions typically for logic circuits supporting memory operations.

The first thick nitride 155 and the TG conductor 120a are removed using a dry etching technique (e.g. RIE). This step exposes filter 52 in non-memory regions 157. The process is further continued by removing the filter 52, the oxide blocks 146, and the first insulator 68 using dry etching technique to expose the substrate 98.

The photo-resist is stripped.

A photo-resist is arranged using a conventional photo-lithography and masking step to selectively expose regions in the non-memory regions for logic transistors having a first type of channel (e.g. n-channel transistors).

The substrate is doped in the exposed regions with proper type of impurity by employing ion implantation techniques. The depth and concentration of the impurity is controlled by the energy and dosage of the impurity ions. Typically, such ion implant is done in one or multi-steps (e.g. an implant step arranging a well, an implant step setting the threshold voltage, and an implant step controlling the punch-through leakage of the transistor).

The structure thus arranged is shown in FIG. 15F wherein the view is shown along a cross-section similar to that shown in ISA but includes the non-memory regions 157. The structure in memory cell regions 156 along other directions are like those shown in FIG. 15A, FIG. 15B, FIG. 15C, FIG. 15D and FIG. 15E.

In FIG. 16F, for second type logic transistors in non-memory regions, a photo-resist using a conventional photo-lithography and masking step is used to selectively expose regions in the non-memory regions for logic transistors of a second type of channel (e.g. p-channel transistors). This step is followed by ion implantation steps implanting impurity to arrange well, set threshold voltage, and set punch-through leakage of the second type of channel transistor using method similar to those described in connection with FIG. 15F.

The steps include stripping the photo-resist.

The steps include arranging a logic insulator 160 over the substrate 98 with thickness preferably in the range from about 7 nm to about 9 nm. The insulator is preferably made of oxide arranged by employing conventional thermal oxidation, HTO, or by in-situ steam generation (“ISSG”) techniques well-known in the art. In the case of having oxide as the logic insulator 160, this step also arranges oxide 160a on sidewalls of the TG conductor 120a.

The steps include arranging a gate conductor 163a such as polysilicon or other types of conductor on the structure by employing conventional deposition techniques (e.g. LPCVD). In the case of polysilicon for the gate conductor, the polysilicon is doped in-situ or by an ion implantation technique. Such gate conductor is arranged on the logic insulator 160 as well as on the first thick nitride 155. The thickness of the gate conductor 163a typically ranges from about 0.05 um to about 0.2 um depending on the technology node chosen.

The steps include arranging an optional layer of oxynitride (not shown) to be used as a hard mask while patterning gates for transistors.

The steps include arranging gate 163a for logic transistors. The process steps include applying a photo-resist and masking step to define the gate and an etching step to remove the gate conductor 163a in regions uncovered by the hard mask. This step also removes the gate conductor on the first thick nitride 155.

The steps include stripping the photo-resist and the hard mask. The finished structure for the memory region 156 and non-memory region 157 is shown in FIG. 16F.

In FIG. 17F, for first type logic transistors in non-memory regions, the steps include arranging shallow diffusion regions (e.g. LDD regions) for the first transistors. This step is done by arranging a photo-resist using a conventional photo-lithography and masking step to selectively expose regions in the non-memory regions for the first channel type of logic transistors. This step is followed by ion implantation steps implanting a proper type of impurity into regions adjacent to the gates 163a and a step of stripping the photo-resist.

The steps include arranging insulators 165 along sidewalls of the gate 163a. This step is done by first depositing a TEOS oxide 164 followed by depositing a nitride. Next, a dry etching step is prearranged to remove nitride on the TEOS oxide 164 to arrange insulators 165 along the sidewalls of gate 163a. The insulators also are arranged along sidewalls of oxide block 146 and of the TG conductor 120a.

The steps include arranging source/drain diffusion regions 168 for the first channel type of transistor. This step is done by arranging a photo-resist using a conventional photo-lithography and masking step to selectively expose regions in the non-memory regions for the first channel type of logic transistors. This step is followed by ion implantation steps implanting impurity of proper type, dosage, and energy into region adjacent to the gate 163a. The photo-resist is stripped after the implantation step.

Source/drain diffusion regions are arranged for the second channel type of transistor using steps similar to those described for the first channel type of transistors. The source/drain regions of the second channel type of transistors have cross-sections like those of the first channel type of transistor. In the drawings illustrated hereafter, therefore, only the first channel type of transistor is shown so as not to complicate the drawings.

The finished structure for the memory region 156 and non-memory region 157 is shown in FIG. 17F.

In FIG. 18F, for second type logic transistors in non-memory regions, the steps include removing the TEOS oxide 164 by employing conventional etching techniques. This step also removes the logic insulator 160 on the source/drain diffusions. The step exposes the top portion of gate 163a and the source/drain diffusions 168 to the air.

The steps include arranging salicide regions 170 on the top portion of gate 163a and the source/drain diffusions 168 by employing conventional salicide techniques. For example, this is done by depositing a layer of metal (e.g. Ni) followed by a thermal treatment (e.g. RTA) to react Ni with the silicon to arrange a Ni-silicon alloy. Un-reacted Ni is then removed by a conventional wet-etching technique to leave the Ni-silicide alloy (salicide 170), which is self-aligned to the conductive regions 163a and 168 lying thereunder.

The finished structure for the memory region 156 and non-memory region 157 is shown in FIG. 18F

In FIG. 19, FIG. 19A, FIG. 19B, FIG. 19C, FIG. 19D, FIG. 19E and FIG. 19F, the TG line formation is depicted. The steps include arranging a plurality of TG lines 120 orientated in the second direction (for example, “column direction”) with each pair of them spaced apart by a third trench 147. This step is done by first arranging an optional layer of oxynitride 171 to be used as a hard mask on the TG conductor 120a, followed by conventional photo-lithography and masking steps to define TG lines 120. Next, a dry etch (e.g. RIE) is performed to remove oxynitride 171 in exposed regions followed by a step stripping the photo-resist. The step is followed by etching the first thick nitride 155, and the TG conductor 120a to expose portions of the filter 52 in the third trench 147. The etching has no effect in non-memory regions, which are covered by the hard mask 171.

The steps include arranging a thin nitride layer on top of the thick nitride layer 155. The thickness of the thin nitride layer is in a range from about 10 nm to about 30 nm depending on the technology node chosen. Typically, the thin nitride thickness is thinner for more advanced technology node. For example, 10 nm (or 0.01 um) for the thin nitride is preferred for a 45 nm node technology.

The steps include a dry etch back of the thin nitride layer by using conventional techniques (e.g. RIE) to arrange sidewall insulators 172 on both sidewalls of the TG conductor. The etch uses the oxynitride 171 as an etch stop. The sidewall insulators may be nitride, oxynitride or any other insulators. In particular embodiments, the sidewall insulators 172 are one or more materials selected from the group consisting of oxide, nitride, oxynitride and alloys thereof. A single material is typical and when more than one material is employed, typically a nitride and an oxide are employed.

The resulting structure of FIG. 19 and the cross-sectional views along lines AA′, BB′, CC′, DD′ and EE′ are shown in FIG. 19A, FIG. 19B, FIG. 19C, FIG. 19D, and FIG. 19E.

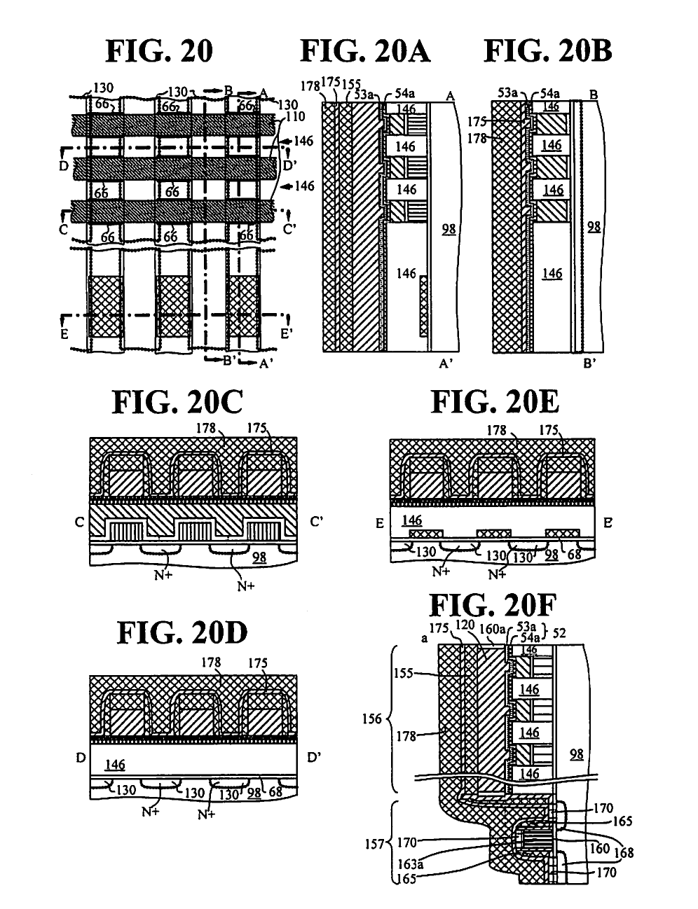

In FIG. 20, FIG. 20A, FIG. 20B, FIG. 20C, FIG. 20D, FIG. 20E and FIG. 20F,

The steps include stripping the oxinitride hard mask 171.

The steps include arranging a thin oxide layer 175 on top of the structure. The oxide layer 175 is arranged by using conventional techniques such as LPCVD or an HTO oxide. The thickness of the oxide layer is in the range from about 10 nm to about 30 nm.

The steps include arranging a second thick insulator such as nitride 178 on top of the thin oxide layer 175 using conventional LPCVD techniques. The thickness of the second thick nitride is chosen such that it provides strain to the TG and BG conductors to effectively generate Piezo-Ballistic transport effect for the charge injection. Typical nitride thickness is from about 20 nm to about 150 nm. The second thick nitride 178 also provides effects on enhancing performance (e.g. current drive and power saving) of the logic transistors and provides the function of a contact etching stopper for arranging borderless contacts as described in connection with FIG. 24 and FIG. 24A through FIG. 24F.

The resulting structure of FIG. 20 is shown with the cross-sections along lines AA′, BB′, CC′, DD′, and EE′ in FIG. 20A, FIG. 20B, FIG. 20C, FIG. 20D and FIG. 20E, respectively.

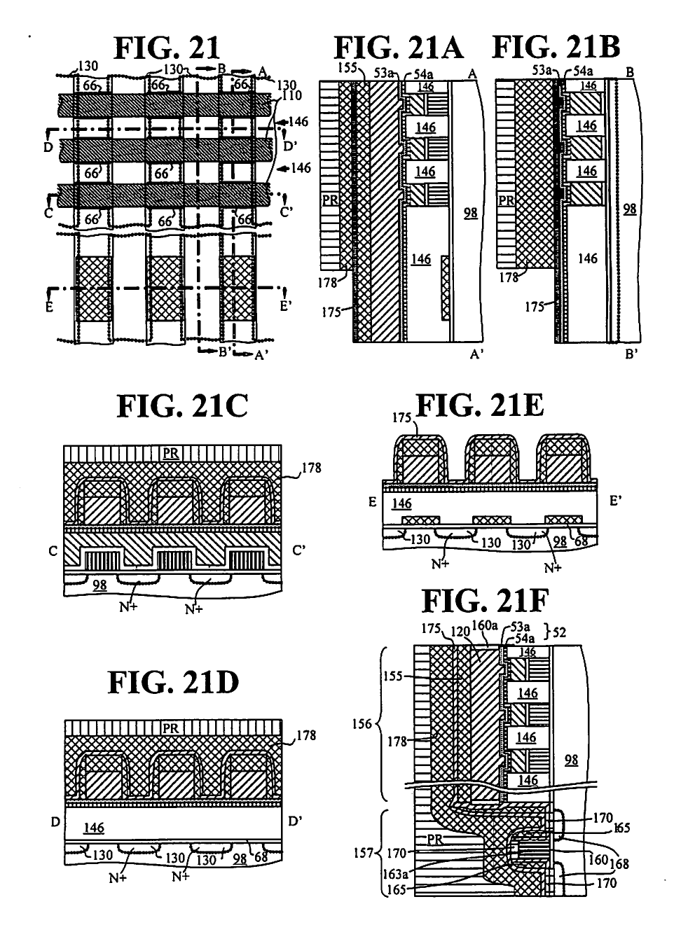

In FIG. 21, FIG. 21A, FIG. 21B, FIG. 21C, FIG. 21D, FIG. 21E and FIG. 21F the steps include arranging a photo-resist (PR) on top of the structure using conventional photo-lithography techniques.

The steps include applying a mask to define the PR exposing a portion of the second thick nitride 178 in regions adjacent to the cell area. The PR thus arranged covers the thick nitride 178 in the rest of the area.

The steps include removing the second thick nitride 178 in the exposed area by using conventional etching techniques (e.g. RIE). This step uses the oxide layer 175 as an etching stop layer.

The resulting structure of FIG. 21 is shown with the cross-sections along lines AA′, BB′, CC′, DD′, and EE′ in FIG. 21A, FIG. 21B, FIG. 21C, FIG. 21D and FIG. 21E, respectively.

In FIG. 22, FIG. 22A, FIG. 22B, FIG. 22C, FIG. 22D, FIG. 22E and FIG. 22F, the steps include removing the PR by using conventional PR striping techniques.

The steps include arranging an ILD dielectric layer 180, for example, by depositing an oxide layer with a thickness in the range from about 100 nm to about 400 nm.

The resulting structure of FIG. 22 is shown with the cross-sections along lines AA′, BB′, CC′, DD′, and EE′ in FIG. 22A, FIG. 22B, FIG. 22C, FIG. 22D and FIG. 22E, respectively.

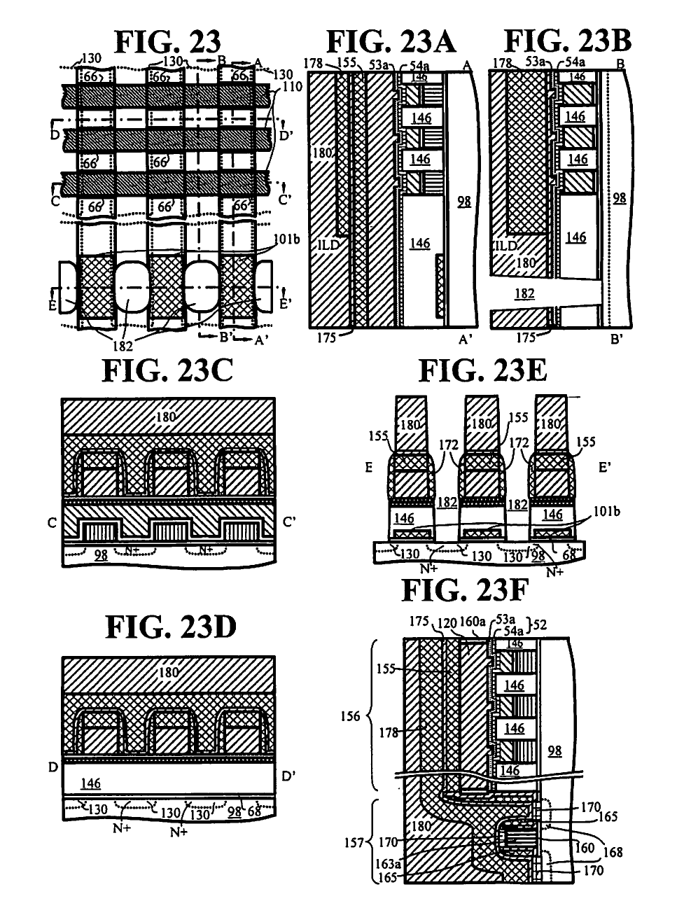

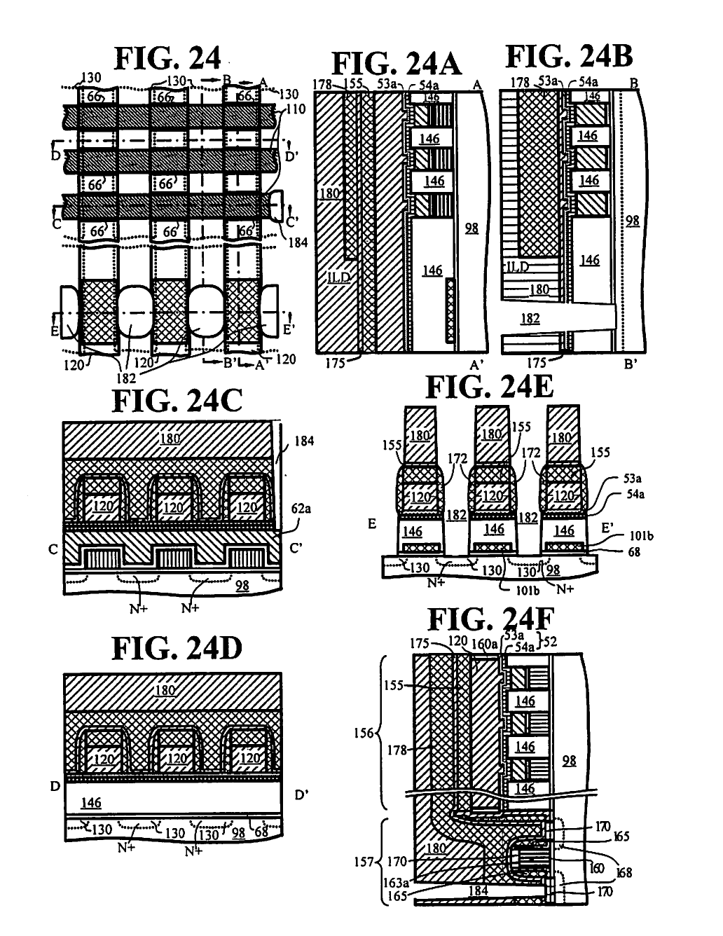

In FIG. 23, FIG. 23A, FIG. 23B, FIG. 23C, FIG. 23D, FIG. 23E and FIG. 23F the steps for completing the self-aligned contacts (SAC) are shown. The steps include arranging a photo-resist (PR) on top of the structure using conventional photo-lithography techniques.

The steps include applying a first type of contact mask to define the PR exposing a portion of the ILD 180. This step defines contact holes 182 for self-aligned contacts (SAC). Such contacts are preferably arranged over the bit lines 130 with each contact hole arranged in between a pair of two adjacent nitride elements 101b.

The steps include removing the exposed ILD layer 180, the thin oxide layer 175, and the TD dielectric 53a using conventional etching technique to expose the first thick nitride 155, the nitride sidewall insulators 172, and the BD layer 54a in the contact holes. The etch stops on these exposed nitride regions.

The steps include removing the exposed BD layer 54a in a time etch to expose oxide region 146. This step is followed by a RIE etch to remove the exposed oxide region 146.

The steps include optional ion implantation to implant impurity (e.g. n-type impurity such as As) into silicon exposed in the contact holes. The energy of the implant is preferably chosen to prevent impurity implanting through the nitride elements 101b.

The steps include stripping the photo-resist.

The resulting structure of FIG. 23 is shown with the cross-sections along lines AA′, BB′, CC′, DD′, and EE′ in FIG. 23A, FIG. 23B, FIG. 23C, FIG. 23D and FIG. 23E, respectively. Referring to FIG. 23E, the self-aligned contact (SAC) hole 182 extends through the cell layers. In order to provide for the aligned location of the self-aligned contact hole 182, the arranging of the nitride elements 101b occurred during the initial deposit of nitride layer 101a as described in connection with FIG. 9 and the subsequent processing to form elements 101b described in connection with FIG. 10.

In the semiconductor device of FIG. 23, the materials and layers are arranged such that the holes and contacts are preferentially constrained to alignment at desired locations. Specifically, the holes 182 are “self-aligned” because the holes 182 are constrained between pairs of insulators 101b (see FIG. 23E) where the insulators 101b are for example nitride material. The holes 182 (and hence the contacts 188 of FIG. 25E in the holes 182) are self-aligned at the desired location between the insulators and hence thereby substantially aligned with the cell lines 130.

In connection with FIG. 24, FIG. 24A, FIG. 24B, FIG. 24C, FIG. 24D, FIG. 24E and FIG. 24F, the Borderless Contact holes Formation steps are described. The steps include arranging a photo-resist (PR) on top of the structure using conventional photo-lithography techniques followed by applying a second type of contact mask to define the PR exposing ILD layer 180. This step defines contact holes 184 for borderless contacts. The contact holes 184 are made for contacting regions including first lines 110 (for example, word-lines), TG lines 120 of memory, gate 163a and source/drain 168 of logic transistors.

The steps include removing the exposed ILD layer using conventional etching techniques to expose the second thick nitride layer 178 (in logic transistor and in WL strap regions) and the first thick nitride 155 in TG line strap regions. The etch stops on the exposed nitride layers 178 and 155.

The steps include removing the exposed thick nitride layers 178 and 155 using conventional nitride etching techniques followed by an oxide etch removing the thin oxide layer 175 in the logic transistor region and the oxide 175 and filter 52 in WL strap region. This step exposes salicide 170 in contact holes 184 for logic transistor and WL conductor 62a in contact holes 184 for WL. The nitride etch also exposes the TG conductor of the TG lines 120 (not shown).

The steps include an optional ion implantation performed to implant impurity (e.g. n-type impurity such as As) into silicon exposed in the contact holes 184.

The steps include stripping the photo-resist.

The resulting structure of FIG. 24 is shown with the cross-sections along lines AA′, BB′, CC′, DD′, and EE′ in FIG. 24A, FIG. 24B, FIG. 24C, FIG. 24D and FIG. 24E, respectively.

It is apparent from the foregoing description that the memory devices have a channel dielectric, a conductor-material system including a conductor-filter system 59 and a conductor-insulator system 60 arranged in a stack of layers. The term “stack of layers” means layers or regions in a semiconductor device juxtaposed each other whether in a vertical, horizontal or any other direction. A “stack of layers” may include one or more additional layers interposed, in juxtaposed relationship, so that reference to a stack of layers includes some or all of the juxtaposed layers or regions. The stack of layers including the channel dielectric 68 and the system 58 include (with reference to FIG. 24E and FIG. 2A) layers or regions including nitride layer 155, nitride insulator 172, lines 120, dielectric 53a, insulator layer 54a, oxide region 146, nitride 101b and dielectric 68. It is apparent from the above description that the system 58 has one or more conductors and the contact holes include sidewall insulators 172 to prevent the contacts (see contact 188) from shorting to the conductors.

In FIG. 25, FIG. 25A, FIG. 25B, FIG. 25C, FIG. 25D, FIG. 25E and FIG. 25F, the steps include arranging contact metal to form contacts 188 and 190 in the contact holes 182 and 184, respectively, using conventional metallization techniques. The contacts 190 are arranged in contact holes 182 substantially in alignment with the cell lines 130 in a self-aligned contact (SAC) manner. Also, the contact holes 182 include sidewall insulators 172 to prevent the contacts 188 from shorting and these sidewall insulators 172 are, for example, formed of nitride.

The resulting structure of FIG. 25 is shown with the cross-sections along lines AA′, BB′, CC′, DD′, and EE′ in FIG. 25A, FIG. 25B, FIG. 25C, FIG. 25D and FIG. 25E, respectively.

The structure of FIG. 25 is further processed to arrange metal layers using conventional metallization techniques such as metal damascene techniques. Photo-lithography and masking steps follow to define metal lines for interconnecting different regions on the structures to complete an IC fabrication.

In FIG. 25D, the diffusion regions 130, in one embodiment, extend only under the memory region 156 (see FIG. 5 and FIG. 25F, for example). In alternative embodiments, one or more of the diffusion regions 130 of FIG. 25D is electrically coupled to one or more of the diffusion regions 168 in FIG. 25F. Accordingly, the non-memory region 157 having embedded logic in the non-memory region 157 has one or more first cell lines 130 (see FIG. 41, FIG. 41D) extending into the non-memory region 157 for electrically coupling the embedded logic through use of a diffusion. A diffusion as described is one of a group consisting of diffusion, contact and any other conductor for electrically coupling from the memory region 156 and the non-memory region 157.

An alternate embodiment commences with the memory cell of FIG. 17F. The steps include removing the TEOS oxide 164 by employing conventional etching techniques. This step also removes the logic insulator 160 on the source/drain diffusions. The step exposes the top portion of gate 163a and the source/drain diffusions 168 to the air.

The steps include arranging a plurality of TG lines 120 orientated in the second direction (for example, “column direction”) with each pair of them spaced apart by a third trench 147. This is done by first arranging an optional layer of oxynitride 171 to be used as a hard mask on the TG conductor 120a, followed by conventional photo-lithography and masking steps to define TG lines 120. Next, a dry etch (e.g. RIE) is performed to remove oxynitride 171 in exposed regions followed by step stripping of the photo-resist. The step is followed by etching the first thick nitride 155, and the TG conductor 120a to expose portions of the filter 52 in the third trench 147. The etching has no effect in non-memory regions, which are covered by the hard mask 171.

The steps include arranging an optional oxide on sidewalls of the TG conductor 120a (not shown).

The steps include doping the WL conductor 62a in the trench 147 regions by employing ion implantation techniques (e.g. implanting phosphorous impurity). The TG lines 120 are protected by the hard mask and the nitride 155 during the implantation, and the implant has no effect on the TG lines 120.

The steps include applying a thermal step to activate the implanted impurity and to diffuse the impurity laterally to dope WL regions under the TG conductor.

The steps include arranging a thin nitride layer on top of the thick nitride layer 155. The thickness of the thin nitride is range from about 10 nm to about 30 nm depending on the technology node chosen. Typically, the thin nitride thickness is thinner for more advanced technology nodes. For example, 10 nm (or 0.01 um) for the thin nitride is preferred for a 45 nm node technology.

The steps include dry etching back the thin nitride layer by using conventional techniques (e.g. RIE) to arrange nitride sidewall insulators 172 on both sidewalls of each TG line 120. The etch uses the oxynitride 171 as an etch stop to protect the first thick nitride 155.

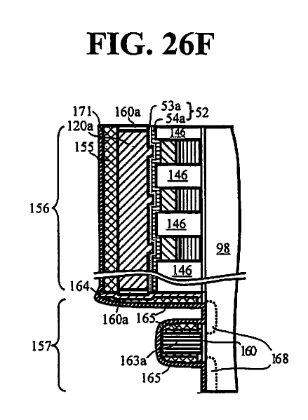

The resulting structure of FIG. 26F has the cross-sections along lines AA′, BB′, CC′, DD′, and EE′ in FIG. 19A, FIG. 19B, FIG. 19C, FIG. 19D and FIG. 19E, respectively, with the differences from FIG. 19F shown in the cross-section in FIG. 26F.

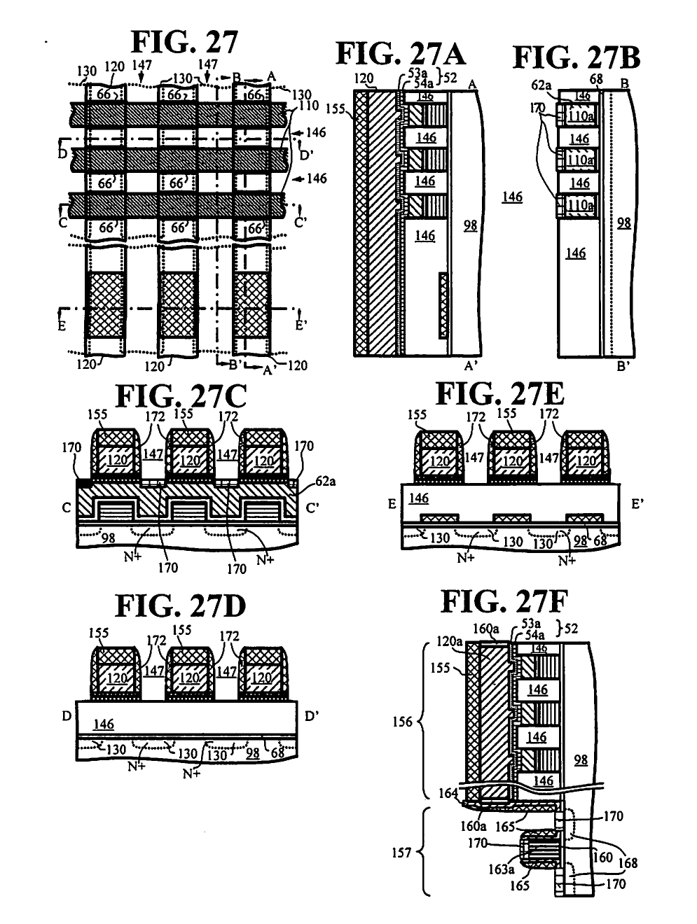

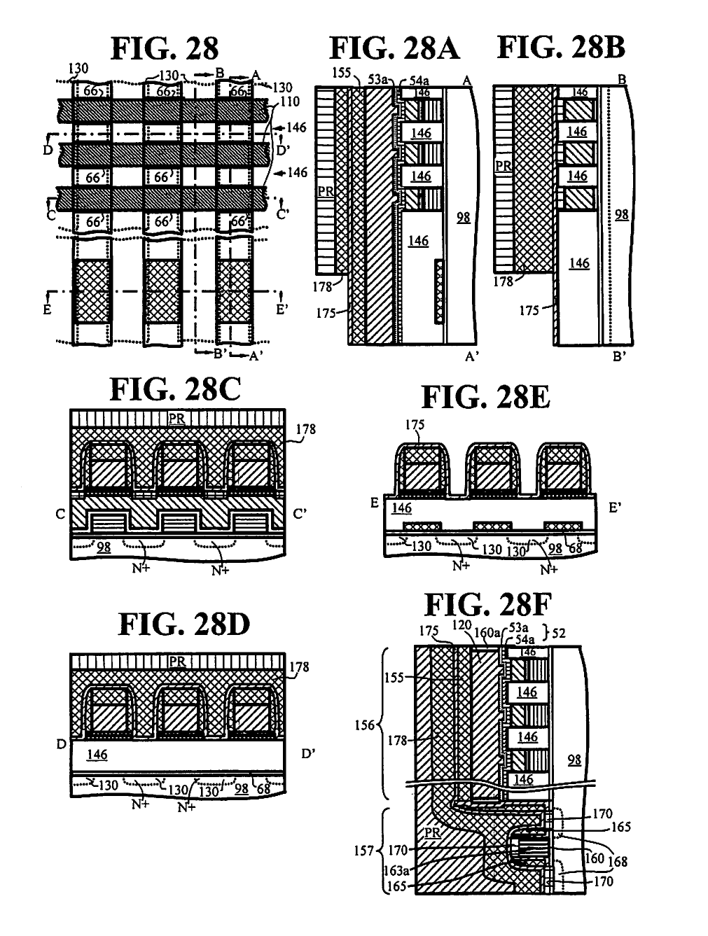

In FIG. 27, FIG. 27A, FIG. 27B, FIG. 27C, FIG. 27D, FIG. 27E and FIG. 27F, the steps include removing the oxynitride 171 by using conventional techniques (e.g. RIE) followed by an oxide etch. The step exposes the top portion of gate 163a and the source/drain diffusions 168 to the air. The etching also removes the TD oxide 53a of filter 52 and exposes BD nitride 54a within trench 147.

The steps include removing the BD nitride 54a of the filter 52 to expose WL conductor 62a in the trench 147 and in the peripheral region of the array (not shown).

The steps include arranging salicide regions 170 on the top portion of gate 163a and the source/drain diffusions 168 by employing conventional salicide techniques. For example, this is done by depositing a layer of metal (e.g. Ni) followed by a thermal treatment (e.g. RTA) to react Ni with the silicon to arrange a Ni-silicon alloy. Un-reacted Ni is then removed by a conventional wet-etching technique to leave the Ni-silicide alloy (salicide 170), which is self-aligned to the conductive regions 163a and 168 lying thereunder. This step also arranges salicide on the exposed WL conductor 62a of each word-line 110.

The resulting structure of FIG. 27 is shown with the cross-sections along lines AA′, BB′, CC′, DD′, and EE′ in FIG. 24A, FIG. 24B, FIG. 24C, FIG. 24D and FIG. 24E, respectively.

In FIG. 28, FIG. 28A, FIG. 28B, FIG. 28C, FIG. 28D, FIG. 28E and FIG. 28F include the step of arranging a thin oxide layer 175 on top of the structure. The oxide layer 175 is arranged by using conventional techniques such as LPCVD or HTO oxide. The thickness of the oxide layer is in the range from about 10 nm to about 30 nm.

The steps include arranging a second thick nitride 178 on top of the thin oxide layer 175 using conventional LPCVD techniques. The thickness of the second thick nitride is chosen such that it provides strain to TG and BG conductors to effectively generate Piezo-Ballistic transport effect for the charge injection. Typical nitride thickness is from about 20 nm to about 150 nm. The second thick nitride 178 also provides effects on enhancing performance (e.g. current drive and power saving) of the logic transistors and provides the function of being a contact etching stopper for arranging borderless contacts. Arrange a photo-resist (PR) on top of the structure using conventional photo-lithography techniques.

The steps include applying a mask to define the PR exposing a portion of the second thick nitride 178 in region adjacent to the cell area. The PR thus arranged covers the thick nitride 178 in the rest of the area.

The steps include removing the second thick nitride 178 in the exposed area by using conventional etching techniques (e.g. RIE). This step uses the oxide layer 175 as an etching stop layer.

The resulting structure of FIG. 28 is shown with the cross-sections along lines AA′, BB′, CC′, DD′, and EE′ in FIG. 24A, FIG. 24B, FIG. 24C, FIG. 24D and FIG. 24E, respectively.

In FIG. 29, FIG. 29A, FIG. 29B, FIG. 29C, FIG. 29D, FIG. 29E and FIG. 29F, the steps include removing the PR by using conventional PR striping techniques.

The steps include arranging an ILD dielectric layer 180, for example, by depositing an oxide layer with a thickness in the range from about 100 nm to about 400 nm.

The steps include arranging a photo-resist (PR) on top of the structure using conventional photo-lithography techniques.

The steps include applying a first type of contact mask to define the PR exposing a portion of the ILD 180. This step defines contact holes 182 for self-aligned contacts (SAC). Such contacts are preferably arranged over the bit lines 130 with each contact hole arranged in between two adjacent contact insulators elements 101b in the form of nitride, oxynitride or any other type of insulator. In general, the contact insulators are one or more materials selected from the group consisting of oxide, nitride, oxynitride and alloys thereof. A single material is typical and when more than one material is employed, typically a nitride and an oxide are employed.

The steps include removing the exposed ILD layer 180, the thin oxide layer 175 using conventional etching techniques to expose the oxide region 146. This step is followed by a RIE etch to remove the exposed oxide region 146. The etching continues to remove the oxide layer 68 to expose the substrate 98.

The steps include an optional ion implantation performed to implant impurity (e.g. n-type impurity such as As) into silicon exposed in the contact holes. The energy of the implant is preferably chosen to prevent impurity implanting through the nitride contact insulators, elements 101b.

The steps include stripping the photo-resist.

The resulting structure of FIG. 29 is shown with the cross-sections along lines AA′, BB′, CC′, DD′, and EE′ in FIG. 29A, FIG. 29B, FIG. 29C, FIG. 29D and FIG. 29E, respectively.

In FIG. 30, FIG. 30C, and FIG. 30F, Borderless Contact holes are arranged. The steps include arranging a photo-resist (PR) on top of the structure using conventional photo-lithography techniques followed by applying a second type of contact mask to define the PR exposing ILD layer 180. This step defines contact holes 184 for borderless contacts. The contact holes 184 are made for contacting regions including first lines 110 (for example, word-lines), TG lines 120 of memory, gate 163a and source/drain 168 of logic transistors.

The steps include removing the exposed ILD layer 180 using conventional etching techniques to expose the second thick nitride layer 178 (in logic transistor and in WL strap regions) and the first thick nitride 155 in TG line strap regions. The etch stops on the exposed nitride layers 178 and 155.

The steps include removing the exposed thick nitride layers 178 and 155 using conventional nitride etching techniques followed by an oxide etch removing the thin oxide layer 175 in logic transistor region and in WL strap region. This step exposes salicide 170 in contact holes 184 for logic transistor and WL conductor 62a in contact holes 184 for WL. The nitride etch also exposes the TG conductor of the TG lines 120 (not shown).

The steps include an optional ion implantation performed to implant impurity (e.g. n-type impurity such as As) into silicon exposed in the contact holes 184.

The steps include stripping the photo-resist.

The resulting structure of FIG. 30 with the cross-sections along lines CC′ and FF′ in FIG. 30C, and FIG. 30F.

Cross-sections along other section lines AA′, BB′, DD′, and EE′ in connection with FIG. 30 are the same as in FIG. 29A, FIG. 29B, FIG. 29D and FIG. 29E, respectively.

The structure of FIG. 29 is further processed in steps described in connection with FIG. 25 and FIG. 25A through FIG. 25F to finish metallization for IC fabrication.

It is apparent from the above description and with reference to FIG. 26F and FIG. 30F, a memory device (such as device 500 in FIG. 5) is provided having a memory region 156 including a memory cell region 159 having a plurality of memory cells 100, each memory cell including a source 95, a drain 97 and a channel 96 between the source and the drain, a channel dielectric 68, a charge storage region 66 and an electrically alterable system 58 in proximity to the charge storage region. The memory device includes a plurality of cell lines (110, 120, 130) extending among the memory cells 100 in the memory region. The memory device includes a connection region 158 including a plurality of contacts 188, each contact electrically coupling to a cell line (130). The memory device includes a non-memory region including embedded logic. The memory device includes one or more isolations 195 and 196 located in the memory device between the memory and non-memory regions, between the memory cell region and the connection region or in any of the memory cell, connection or non-memory regions. The isolations 195 and 196 employ any suitable isolation scheme, such as LOCOS isolation or shallow-trench isolation (STI). In one embodiment, the cell lines include bit lines (130) occurring at a bit line pitch (P). Additionally, isolation 196 is located in the direction of the cell lines 130. In FIG. 5, the isolation 196 occurs at an isolation pitch (P₁) where the isolation pitch (P₁) is greater than the bit line pitch (P) so that there is not an isolation 196 for each cell line (bit line) 130.

In one embodiment, no isolation region is included in either the memory cell region 156 or in the connection region 158 or no isolation region is included in both the memory cell region 156 and the connection region 158.

While the invention has been particularly shown and described with reference to preferred embodiments thereof it will be understood by those skilled in the art that various changes in arrange and details may be made therein without departing from the scope of the invention.

1. A memory device comprising,
a memory cell region including,
a plurality of memory cells, each memory cell including,
a source, a drain and a channel between the source and the drain,
a channel dielectric,
a charge storage region,
an electrically alterable conductor-material system in proximity to the charge storage region,
a plurality of cell lines extending among the memory cells,
a plurality of contacts.
a connection region for electrically coupling one or more of the contacts and one or more of the cell lines,
a non-memory region having embedded logic.

2. The memory device of claim 1 wherein,
the conductor-material system includes,
a first conductive region;
a dielectric region;
a second conductive region disposed adjacent to and insulated from the first conductive region by the dielectric region;
and wherein the charge storage region is a third region disposed adjacent to and insulated from the second conductive region.

3. The memory device of claim 1 wherein the contacts are selected from the group consisting of self-aligned contacts, borderless contacts and combinations thereof.

4. The memory device of claim 1 wherein one or more of the contacts are in contact holes arranged substantially in alignment with the cell lines, wherein the conductor-material system has one or more conductors, and wherein the contact holes include sidewall insulators to prevent the contacts from shorting to the conductors.

5. The memory device of claim 4 wherein the sidewall insulators are one or more materials selected from the group consisting of oxide, nitride, oxynitride and alloys thereof.

6. The memory device of claim 1 wherein the connection region includes a plurality of contact insulators where each of one or more of the contacts is located in proximity to a pair of the contact insulators.

7. The memory device of claim 6 wherein the contact insulators are one or more materials selected from the group consisting of oxide, nitride, oxynitride and alloys thereof.

8. The memory device of claim 1 wherein the plurality of cell lines includes first cell lines extending into the connection region, wherein one or more of the contacts are first contacts in the connection region and wherein one or more of the first contacts are electrically coupled to one or more of the first cell lines.

9. The memory device of claim 8 wherein the connection region further includes a plurality of contact insulators, each of the contact insulators aligned substantially between pairs of the first cell lines, and wherein each pair of the contact insulators has one or more of the first contacts arranged substantially there between.

10. The memory device of claim 1 wherein the non-memory region includes one or more of the contacts as non-memory region contacts and where one or more of the non-memory region contacts electrically couples to one or more of the cell lines.

11. The memory device of claim 1 wherein the plurality of cell lines includes one or more first cell lines extending into the non-memory region where one or more of the first cell lines electrically couples the embedded logic without an intermediary element or with a conductive intermediary element.

12. The memory device of claim 11 wherein the conductive intermediary element is selected from the group consisting of contacts, diffusions, metal lines and transistors or combinations thereof.

13. The memory device of claim 1 wherein the embedded logic includes one or more transistors, each transistor having transistor terminals and wherein at least one transistor terminal is electrically coupled to at least one of the cell lines.

14. The memory device of claim 1 wherein the connection region includes a first connection region and one or more of the contacts are first contacts in the first connection region and further including a second connection region wherein one or more of the contacts are second contacts in the second connection region wherein one or more of the plurality of cell lines includes first cell lines extending to the first connection region for electrically coupling to one or more of the first contacts and includes second cell lines extending to the second connection region for electrically coupling to one or more of the second contacts.

15. A memory device comprising,
a memory cell region including,
a plurality of memory cells arrayed at a cell pitch, each memory cell including,
a source, a drain and a channel between the source and the drain,
a channel dielectric,
a charge storage region,
an electrically alterable conductor-material system in proximity to the charge storage region,
a plurality of cell lines extending from cell to cell and arrayed substantially at the cell pitch,
a plurality of contacts arrayed substantially at the cell pitch, one or more of the contacts electrically coupling to one or more cell lines.

16. The memory device of claim 15 further including a connection region wherein first contacts of the plurality of contacts are in the connection region wherein the connection region includes a plurality of contact insulators, each of the contact insulators aligned substantially between pairs of the cell lines and wherein each pair of the contact insulators has one or more of the first contacts arranged substantially there between.

17. The memory device of claim 15 further including a non-memory region having embedded logic and wherein the plurality of cell lines includes one or more first cell lines extending into the non-memory region, the first cell lines electrically coupling the embedded logic without an intermediary element or with a conductive intermediary element.

18. The memory device of claim 17 wherein the conductive intermediary element is selected from the group consisting of contacts, diffusions, metal lines and transistors or combinations thereof.

19. The memory device of claim 17 wherein the embedded logic includes one or more transistors, each transistor having a first terminal, a second terminal and a gate terminal and wherein for one or more of the transistors, the first terminal electrically couples to a first non-memory region contact, the second terminal electrically couples to a second non-memory region contact and the gate electrically couples to a gate non-memory region contact.

20. The memory device of claim 19 wherein,
a first one of the transistors has a first-transistor first terminal electrically coupled to a first one of the first cell lines, has a first-transistor second terminal electrically coupled to a second one of the first cell lines whereby enabling a first-transistor gate electrically couples the first one of the first cell lines and the second one of the first cell lines.

21. The memory device of claim 19 wherein,
a first one of the transistors has a first-transistor first terminal connected to a first one of the first cell lines, has a first-transistor second terminal connected to a second one of the first cell lines whereby enabling a first-transistor gate electrically couples the first one of the first cell lines and the second one of the first cell lines,
a second one of the transistors has a second-transistor first terminal connected to the second one of the first cell lines, has a second-transistor second terminal connected to a third one of the first cell lines whereby enabling a second-transistor gate electrically couples the second one of the first cell lines and the third one of the first cell lines.

22. A method of arranging a memory device comprising,
in a memory region,
arranging a memory cell region including,
arranging a plurality of memory cells, including for each memory cell,
arranging a source, a drain and a channel between the source and the drain,
arranging a channel dielectric,
arranging a charge storage region,
arranging an electrically alterable conductor-material system in proximity to the charge storage region,
arranging a plurality of contacts.
arranging a connection region for electrically coupling one or more of the contacts and one or more of the cell lines,
arranging a non-memory region having embedded logic.

23. The method of claim 22 including arranging the plurality of contacts selected from the group consisting of arranging self-aligned contacts, arranging borderless contacts and combinations thereof.

24. A memory device comprising:
a non-memory region,
a memory region including,
a memory cell region having,
a plurality of memory cells, each memory cell including,
a source, a drain and a channel between the source and the drain,
a channel dielectric,
a charge storage region,
an electrically alterable conductor-material system in proximity to the charge storage region,
a connection region including a plurality of contacts, each contact electrically coupling to a cell line,
a plurality of cell lines extending among the memory cells in the memory region,
one or more isolations in the memory device.

25. A memory device of claim 24 wherein the plurality of cell lines include bit lines at a bit-line pitch and wherein isolation is included in the memory cell region occurring at an isolation pitch greater than the bit-line pitch.
